(19) United States
(12) Patent Application Publication
(10) Pub. No.: US 2019/0115448 A1
(43) Pub. Date: Apr. 18, 2019

(54) III-NITRIDE VERTICAL TRANSISTOR WITH APERTURE REGION FORMED USING ION IMPLANTATION

(71) Applicant: The Regents of the University of California, Oakland, CA (US)

(72) Inventors: Srabanti Chowdhury, San Ramon, CA (US); Dong Ji, Tempe, AZ (US)

(73) Assignee: The Regents of the University of California, Oakland, CA (US)

(21) Appl. No.: 16/092,154

(22) PCT Filed: May 11, 2017
(86) PCT No.: PCT/US2017/032253

§ 371 Date: Oct. 8, 2018

Related U.S. Application Data
(60) Provisional application No. 62/335,460, filed on May 12, 2016.

(51) Int. Cl. H01L 29/66; H01L 29/778; H01L 29/08; H01L 21/02; H01L 29/06

(52) U.S. Cl. CPC H01L 29/66462; H01L 29/7788; H01L 29/66977; H01L 29/66666; H01L 29/0843; H01L 29/2003; H01L 21/0257; H01L 21/0262; H01L 29/66909; H01L 29/0646; H01L 21/0254

(57) ABSTRACT

III-nitride vertical transistors and methods of making the same are disclosed. The transistors can include aperture regions that are formed using ion implantation. The resulting transistors can have improved properties.

### CROSS-REFERENCE TO RELATED APPLICATIONS

This application claims the benefit of U.S. Provisional Application Ser. No. 62/335,460, entitled “III-Nitride Vertical Transistor with Aperture Region Formed Using Ion Implantation,” by inventors Srabanti Chowdhury and Dong Ji, Attorney Docket Number 112624.00697.M16-222P, filed on 12 May 2016, the contents of which are incorporated by reference herein.

### STATEMENT REGARDING FEDERALLY SPONSORED RESEARCH

This invention was made with U.S. government support under award number DE-AR0000451 awarded by the Department of Energy (DOE). The U.S. government has certain rights in the invention.

### BACKGROUND OF THE INVENTION

The disclosure relates generally to the field of electronic devices. More particularly, the disclosure relates to current aperture vertical electron transistors (CAVETs), lateral channel vertical junction field-effect transistors (LC-VJFETs) and vertical metal-oxide-semiconductor field-effect transistors (VMOSFETs), comprising a p-type GaN current blocking layer (CBL) formed by doping and an current aperture region formed by ion implantation.

Gallium nitride (GaN) is becoming the material of choice for power electronics to enable the roadmap of increasing power density by simultaneously enabling high-power conversion efficiency and reduced form factor. This is because the low switching losses of GaN enable high-frequency operation which reduces bulky passive components with negligible change in efficiency. Commercialization of GaN-on-Si materials for power electronics has led to the entry of GaN devices into the medium-power market since the performance-over-cost of even first-generation products looks very attractive compared to today's mature Si-based solutions. On the other hand, the high-power market still remains unaddressed by lateral GaN devices. The current and voltage demand for high-power conversion application makes the chip area in a lateral topology so large that it becomes difficult to manufacture. Vertical GaN devices would play a big role alongside silicon carbide (SiC) to address the high-power conversion needs.

Power conversion is ubiquitous in our everyday lives. It plays a role from charging our cell phone to powering our home. Power conversion could mean stepping up or stepping down from one voltage level to another (boost or buck) or a conversion from dc to an ac voltage (inverter) or from 1-phase to 3-phase (phase converter), or just isolating from the supply line (power factor correction). A switch can be regarded as the heart of any power conversion unit. An ideal switch is one which offers an infinite resistance to current in its OFF-state and zero resistance when in its ON-state. In solid state power electronics application a switch is realized by a transistor in its class D or higher operation. With advancement in solid state technologies the whole range of power electronics application can be addressed by solid state devices. According to a 2012 Presentation by Yole Development at CS-Europe (hosted by Compound Semiconductor), the range of power applications that can be addressed with GaN is shown in FIG. 1.

Si transistors have been providing the solutions for the entire range of voltages needed for power conversion ranging from 100s of Watts to Megawatts with various devices like MOSFETs, IGBTs, SJTs, BJTs and thyristors. However the advent of wide bandgap (WBG) materials, and their rapid technological progress, promises enhanced performance beyond the Si roadmap. The higher critical electric field (E_{c}) due to the large bandgap of these materials makes them ideal for high-power electronics applications. Increasing operating voltages need higher V_{bd} and higher efficiencies need lower R_{ON} which is simultaneously best served by WBG materials.

GaN devices can be configured in a lateral or vertical configuration. In a typical lateral device, a thin layer of AlGaN is grown on top of the GaN channel to take advantage of the high mobility (˜2000 cm² V⁻¹ s⁻¹) two-dimensional electron gas (2DEG) formed at the AlGaN/GaN interface, which is used as the current carrying layer. The source, drain, and gate are fabricated on the same plane on the top of the typical lateral device. Electrons are modulated by the gate and flow from the source to the drain, where source-drain distance is primarily responsible for the blocking voltage in the off-state. However, for higher power (>10 kW) applications where higher breakdown voltages (>1.2 kV) are required, the lateral topology becomes increasingly unattractive both in cost and manufacturability due to the very large chip areas required by the breakdown voltages at the required current level (typically over 20 A).

Vertical topologies become more economical and viable for such a range of high power applications. A typical vertical device has a source and gate on the top and the drain on the bottom. One common example is a current aperture vertical electron transistor (CAVET). The current is controlled by the gate and the current flows through the bulk of the material into the drain. The horizontal high-mobility electron channel achieved by the AlGaN/GaN layer is used in conjunction with a thick GaN drift region in order to achieve low R_{ON} and a high breakdown voltage. Current blocking layers (CBL) are achieved by either p-type doping of the GaN layer or by implantation of a material like Mg or Al. In both cases, the devices require an aperture through which the current will flow. In existing technology, the CBLs are thus fashioned by applying a mask in the shape of the aperture, implanting the CBLs in the regions not covered by the mask, and regrowing the remainder of the GaN device. However, this regrowth process involves an interruption of a single crystal growth, which tends to produce imperfections at an interface where regrowth is performed. Alternatively doped (p-type) CBL can be formed by growth or regrowth. Let us call the structure prior to regrowth as the “Base structure” and the regrown structure as the “Regrown structure”. If the CBL, formed by doping, is a part of the base structure then the CBL in the aperture region needs to be etched and then the aperture region needs to be regrown in order to complete the device structure. If the aperture region is realized in the base structure then the CBL region is achieved by first etching the aperture layer in the designated CBL region and regrowing the CBL region with suitable doping. In either method regrowth is essential to fully fabricate the device.

The majority of GaN devices are produced with materials grown with Ga-polarity in the c-plane. Accordingly, the majority of current GaN device designs cannot achieve functions that are achievable by material properties that require materials grown with N-polarity.

Previously, vertical GaN transistors has been fabricated with implanted or regrown CBL. Let us call the structure prior to regrowth as the “base structure” and the regrown structure as the “regrown structure”. A base structure can be epitaxially grown by metal-organic chemical vapor deposition (MOCVD) with n-type GaN, and the CBL region is formed by first etching the aperture layer in the designated CBL region and regrown the CBL region with suitable doping, or by implantation of a material like Mg or Al using a mask cover the aperture region. Both existing technology have enabled functioning devices. Nonetheless, in order to hold high off-state voltage, for example, an off-state voltage larger than 600V, a doped CBL layer should be as a part of the base structure.

Consequently, considering such limitations of previous technological approaches, it would be desirable to have a system and method for a producing a III-nitride vertical transistor with the above-mentioned functionality, but produced without a regrowth step.

### SUMMARY OF THE INVENTION

The present disclosure overcomes the aforementioned drawbacks by presenting semiconductor structures, devices, and III-nitride vertical transistors, and methods of making and using the same.

In accordance with the present disclosure, a semiconductor device can include a current blocking layer and aperture region. The current blocking layer and aperture region may be comprised of the same material. The current blocking layer and aperture region may be formed by polarization engineering and not doping or implantation. The semiconductor device can further include a drain; a barrier layer disposed in a first direction relative to the drain and in electronic communication with the drain, the barrier layer comprising the current blocking layer and the aperture region; a two-dimensional electron gas-containing layer disposed in the first direction relative to the barrier layer; a gate electrode oriented to alter the energy levels of the aperture region when a gate voltage is applied to the gate electrode; and a source in ohmic contact with the two-dimensional electron gas-containing layer.

In accordance with the present disclosure, a method of making a semiconductor device can include obtaining, growing, or forming a N-polar GaN substrate comprising a functional bilayer comprising a barrier layer and a two-dimensional electron gas-containing layer disposed in a first direction relative to the barrier layer, the barrier layer formed without a regrowth step. The method can further include one or more of the following steps: removing a portion of the functional bilayer to form a gate region; depositing a dielectric material in the gate region and atop the two-dimensional electron gas-containing layer in the first direction relative to the two-dimensional electron gas-containing layer; removing two portions of the dielectric material atop the two-dimensional electron gas-containing layer to form source regions; forming source electrodes in ohmic contact with the two-dimensional electron gas-containing layer in the source regions; forming a gate electrode atop the dielectric material in the gate region; and forming a drain disposed in a second direction opposite the first direction relative to the functional bilayer.

In accordance with the present disclosure, a method of making a semiconductor device can include one or more of the following steps: obtaining, growing, or forming a N-polar GaN substrate comprising functional bilayer comprising a barrier layer and a two-dimensional electron gas-containing layer disposed in a first direction relative to the barrier layer, the functional bilayer formed without a regrowth step; forming a source electrode in ohmic contact with the two-dimensional electron gas-containing layer; forming a gate electrode oriented to provide alter the energy levels of the barrier layer to form an aperture region when a gate voltage is applied exceeding a threshold voltage; and forming a drain disposed in a second direction relative to the barrier layer, the second direction opposite the first direction.

In accordance with the present disclosure, a method for fabricating a semiconductor device comprises: obtaining, growing, or forming a GaN substrate, which includes a p-type current-blocking layer; implanting Si, O, or H into the p-type current-blocking layer to form a current-aperture region for the semiconductor device; and high-temperature annealing the substrate with the layers grown on top and implanted, thereby removing implantation-induced damage and electrically reactivating the current-aperture region.

In some embodiments, the current-blocking layer is exposed during the implanting.

In some embodiments, the current-blocking layer is buried by other III-Nitride layers during the implanting.

In some embodiments, the current-blocking layer is buried by a sacrificial mask layer during the implanting.

In some embodiments, the method further comprises forming (Al, Ga, In) N layers above the current-aperture region through regrowth in a growth chamber.

In some embodiments, the (Al, Ga, In) N layers are formed during an initial growth, which occurs before the implantation of the current-aperture region.

In some embodiments, the (Al, Ga, In) N layers are formed by regrowth through Molecular Beam Epitaxy (MBE) or Metal organic chemical vapor deposition (MOCVD).

In some embodiments, (Al, In, Ga) N structures in the semiconductor device are grown Nitrogen-polar.

In some embodiments, (Al, In, Ga) N structures in the semiconductor device are grown Ga-polar.

In some embodiments, growth of the semiconductor device structure is achieved by Molecular Beam Epitaxy (MBE) under a plasma or nitrogen-rich environment.

In some embodiments, growth of the semiconductor device structure is achieved by metal organic chemical vapor deposition.

In some embodiments, the method further comprises forming one or more source contacts on the GaN substrate.

In some embodiments, the one or more source contacts are formed through an annealing process.

In some embodiments, the one or more source contacts are formed through an implantation process.

In some embodiments, the semiconductor device comprises a lateral channel vertical junction field-effect transistor.

In some embodiments, the semiconductor device comprises a vertical electron transistor having at least one gate formed on an etched sidewall.

In some embodiments, the semiconductor device includes a dielectric layer comprised of an oxide-based dielectric.

In some embodiments, the semiconductor device includes a dielectric layer comprised of a non-oxide-based dielectric.

In some embodiments, the method further comprises: creating one or more vias to expose at least a portion of the p-doped current-blocking layer positioned outside the current-aperture region; and annealing the semiconductor device structure in the absence of hydrogen gas at a temperature above 600° C., thereby reactivating the at least a portion of the p-type current-blocking layer positioned outside the current-aperture region.

In some embodiments, the semiconductor device comprises a diode.

In some embodiments, the semiconductor device comprises a transistor.

In some embodiments, a field-plated structure comprises part of a gate of the transistor for electric field management.

In some embodiments, a field-plated structure comprises part of a source of the transistor for electric field management.

In some embodiments, a field-termination region resides in the vicinity of a high electric field region in the semiconductor device during off-state semiconductor device operation.

In some embodiments, the field-termination region is formed by implantation or diffusion of dopants, or regrowth of p-type wells.

In some embodiments, the field-termination region may or may not be active.

In some embodiments, a drain contact for the semiconductor device is located on a back of the wafer or substrate.

In some embodiments, a drain contact for the semiconductor device is located on a side surface formed by etching away top layers of the semiconductor device to form a via.

The foregoing and other aspects and advantages of the disclosure will appear from the following description. In the description, reference is made to the accompanying drawings which form a part hereof, and in which there is shown by way of illustration a preferred embodiment of the disclosure. Such embodiment does not necessarily represent the full scope of the disclosure, however, and reference is made therefore to the claims and herein for interpreting the scope of the disclosure.

### BRIEF DESCRIPTION OF THE DRAWINGS

FIG. 1 is a graph showing the range of power applications that can be addressed with GaN.

FIG. 2 is a schematic of the semiconductor structure (left) and III-nitride vertical transistor (right) of Example 1.

FIG. 3 is a schematic of a vertical transistor having a tunneling control electrode (TCE) according to one aspect of the disclosure.

FIG. 4 is a flowchart showing a method in accordance with one aspect of the present disclosure.

FIG. 5a is a schematic representation of one step of a method in accordance with one aspect of the present disclosure.

FIG. 5b is a schematic representation of one step of a method in accordance with one aspect of the present disclosure.

FIG. 5c is a schematic representation of one step of a method in accordance with one aspect of the present disclosure.

FIG. 5d is a schematic representation of one step of a method in accordance with one aspect of the present disclosure.

FIG. 5e is a schematic representation of one step of a method in accordance with one aspect of the present disclosure.

FIG. 5f is a schematic representation of one step of a method in accordance with one aspect of the present disclosure.

FIG. 5g is a schematic representation of one step of a method in accordance with one aspect of the present disclosure.

FIG. 6a is a schematic of a vertical transistor according to one aspect of the disclosure.

FIG. 6b is an energy band diagram of the vertical transistor of FIG. 6a with a gate bias of 5 V showing a current pathway that is unavailable due to a high barrier (route 1).

FIG. 6c is an energy band diagram of the vertical transistor of FIG. 6a with a gate bias of 5 V showing a current pathway that is available due to a field effect (route 2).

FIG. 6d is an energy band diagram of the vertical transistor of FIG. 6a with a gate bias of 5 V showing the energy band bending that is induced by a gate bias (route 3).

FIG. 7a shows energy band diagrams of route 1 for the vertical transistor shown in FIG. 6a with a gate bias of 0 V.

FIG. 7b shows an energy band diagram of route 2 for the vertical transistor shown in FIG. 6a with a gate bias of 0 V.

FIG. 8a shows a plot of the output I_{d}-V_{d} curves for the transistor of Example 1 at varying gate voltages at a first zoom level.

FIG. 8b shows a plot of the output I_{d}-V_{d} curves for the transistor of Example 1 at varying gate voltages at a second zoom level.

FIG. 9 is a plot of the I_{d}-V_{g} curve for the transistor of Example 1 on a logarithmic scale (main) and linear scale (inset).

FIG. 10 is a schematic of the semiconductor structure (left) and III-nitride vertical transistor (right) of Example 2. Two cross-sections are represented by numerals 1 and 2.

FIG. 11 is a plot of the energy band diagram along the cross-sections identified in FIG. 10.

FIG. 12 is a flowchart showing a method in accordance with one aspect of the present disclosure.

FIG. 13a is a schematic representation of one step of a method in accordance with one aspect of the present disclosure.

FIG. 13b is a schematic representation of one step of a method in accordance with one aspect of the present disclosure.

FIG. 13c is a schematic representation of one step of a method in accordance with one aspect of the present disclosure.

FIG. 13d is a schematic representation of one step of a method in accordance with one aspect of the present disclosure.

FIG. 13e is a schematic representation of one step of a method in accordance with one aspect of the present disclosure.

FIG. 13f is a schematic representation of one step of a method in accordance with one aspect of the present disclosure.

FIG. 13g is a schematic representation of one step of a method in accordance with one aspect of the present disclosure.

FIG. 13h is a schematic representation of one step of a method in accordance with one aspect of the present disclosure.

FIG. 14 is a flowchart showing a method in accordance with one aspect of the present disclosure.

FIG. 15a is a schematic representation of one step of a method in accordance with one aspect of the present disclosure.

FIG. 15b is a schematic representation of one step of a method in accordance with one aspect of the present disclosure.

FIG. 15c is a schematic representation of one step of a method in accordance with one aspect of the present disclosure.

FIG. 15d is a schematic representation of one step of a method in accordance with one aspect of the present disclosure.

FIG. 15e is a schematic representation of one step of a method in accordance with one aspect of the present disclosure.

FIG. 15f is a schematic representation of one step of a method in accordance with one aspect of the present disclosure.

FIG. 15g is a schematic representation of one step of a method in accordance with one aspect of the present disclosure.

FIG. 16 is a flowchart showing a method in accordance with one aspect of the present disclosure.

FIG. 17a is a schematic representation of one step of a method in accordance with one aspect of the present disclosure.

FIG. 17b is a schematic representation of one step of a method in accordance with one aspect of the present disclosure.

FIG. 17c is a schematic representation of one step of a method in accordance with one aspect of the present disclosure.

FIG. 17d is a schematic representation of one step of a method in accordance with one aspect of the present disclosure.

FIG. 17e is a schematic representation of one step of a method in accordance with one aspect of the present disclosure.

FIG. 17f is a schematic representation of one step of a method in accordance with one aspect of the present disclosure.

FIG. 17g is a schematic representation of one step of a method in accordance with one aspect of the present disclosure.

FIG. 17h is a schematic representation of one step of a method in accordance with one aspect of the present disclosure.

FIG. 17i is a schematic representation of one step of a method in accordance with one aspect of the present disclosure.

FIG. 18 is a schematic representation of a device in accordance with one aspect of the present disclosure.

FIG. 19 is a data plot, as described in Example 3.

FIG. 20 is a data plot, as described in Example 3.

FIG. 21 is a data plot, as described in Example 3.

FIG. 22 is a data plot, as described in Example 4.

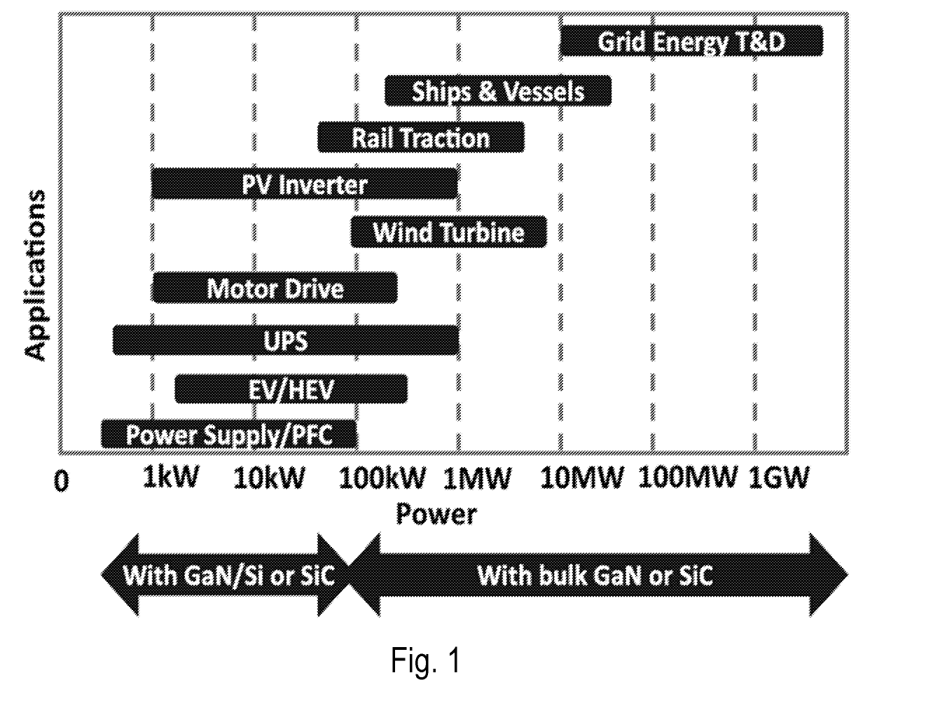

### DETAILED DESCRIPTION OF THE INVENTION

Before the present invention is described in further detail, it is to be understood that the invention is not limited to the particular embodiments described. It is also to be understood that the terminology used herein is for the purpose of describing particular embodiments only, and is not intended to be limiting. The scope of the present invention will be limited only by the claims.

As used herein, the singular forms “a”, “an”, and “the” include plural embodiments unless the context clearly dictates otherwise.

Specific structures, devices, transistors, and methods relating to III-nitride vertical transistors have been disclosed. It should be apparent to those skilled in the art that many additional modifications beside those already described are possible without departing from the inventive concepts. In interpreting this disclosure, all terms should be interpreted in the broadest possible manner consistent with the context. Variations of the term “comprising” should be interpreted as referring to elements, components, or steps in a non-exclusive manner, so the referenced elements, components, or steps may be combined with other elements, components, or steps that are not expressly referenced. Embodiments referenced as “comprising” certain elements are also contemplated as “consisting essentially of” and “consisting of” those elements.

The terms “(AlInGaN)” “(In,Al)GaN”, or “GaN” as used herein (as well as the terms “III-nitride,” “Group-III nitride”, or “nitride,” used generally) refer to any alloy composition of the (Ga,Al,In,B)N semiconductors having the formula Ga_{w}AlₓIn_{y}B_{z}N where 0≤w≤1, 0≤x≤1, 0≤y≤1, 0≤z≤1, and w+x+y+z=1. These terms are intended to be broadly construed to include respective nitrides of the single species, Ga, Al, In and B, as well as binary, ternary and quaternary compositions of such Group III metal species. Accordingly, it will be appreciated that the discussion of the disclosure hereinafter in reference to GaN and AlGaN materials is applicable to the formation of various other (Ga,Al,In,B)N material species. Further, (Ga,Al,In,B)N materials within the scope of the disclosure may further include minor quantities of dopants and/or other impurity or inclusional materials, unless otherwise explicitly stated.

This disclosure provides semiconductor structures, devices, III-nitride vertical transistors, and methods of making and using the same.

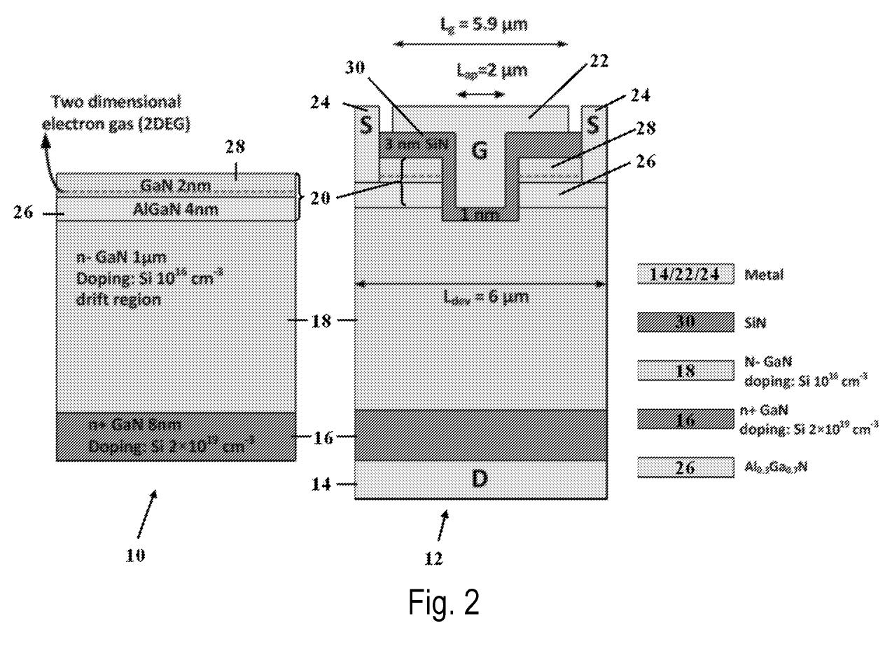

Referring to FIG. 2, in certain aspects, the semiconductor structure 10, device 12, or III-nitride vertical transistor 12 of the present disclosure may comprise one or more of the following: a drain 14; a substrate (not shown in FIG. 2); a current spreading layer 16; a drift layer 18; a functional bilayer 20, a gate 22, and a source 24.

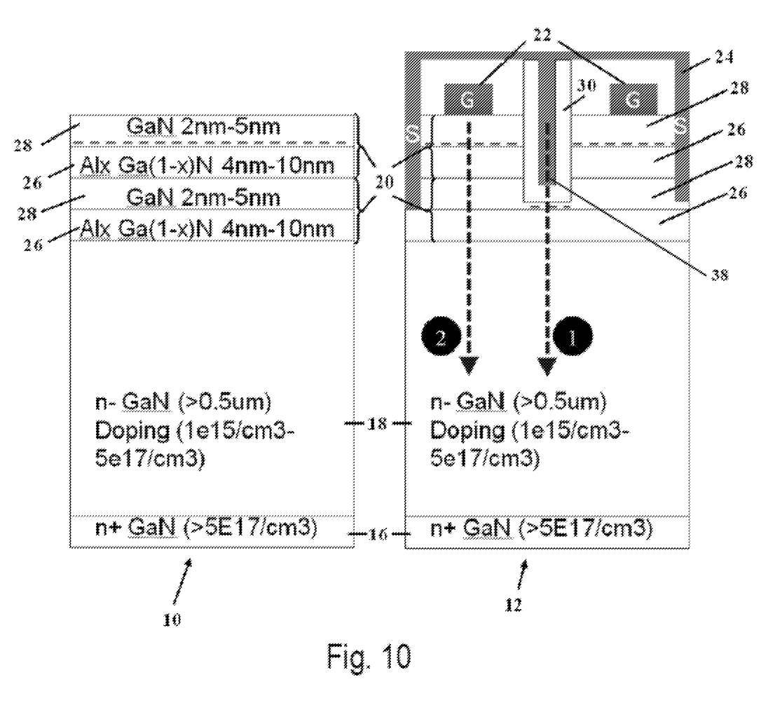

The device 12 or III-nitride vertical transistor 12 may further comprise a source connected field plate (SCFP). The SCFP may provide an electronic environment that enables a 2DEG to be formed at an appropriate place within the device 12 or transistor 12. Referring to FIG. 10, one non-limiting example of a SCFP 38 is shown.

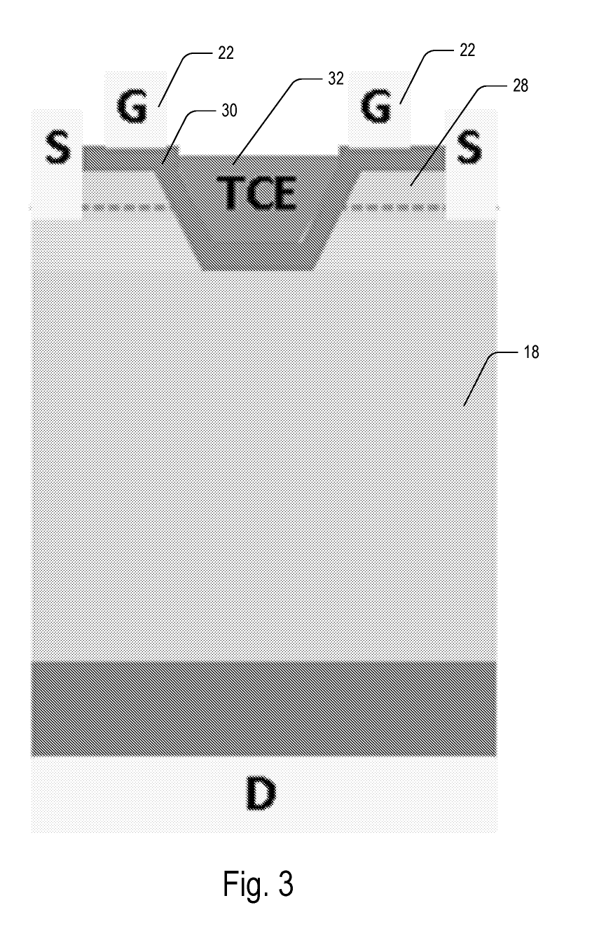

The device 12 or III-nitride vertical transistor 12 may further comprise a tunneling control electrode (TCE) 32. The TCE 32 can be used to control tunneling by manipulating the energy bands of surrounding materials or layers. An aspect of the device 12 or III-nitride vertical transistor 12 of the disclosure having a TCE 32 is shown in FIG. 3, with the device 12 or transistor 12 having the same underlying semiconductor structure as shown in FIG. 2.

A drain 14 may serve as the base of the semiconductor structure 10, device 12, or III-nitride vertical transistor 12 of the present disclosure. The drain 14 is the target for the flow of electrons through the device 12 or III-nitride vertical transistor 12. A drain 14 may comprise a drain material. In principle, any material that functions suitably as a drain and allows growth of a layer coupled to and disposed adjacent to the drain in the vertical direction may be used with the present disclosure.

In certain aspects, the drain 14 may have a thickness ranging from about 1 nm to about 2.0 mm.

A substrate may be coupled to the drain 14 and disposed adjacent to the drain 14 in the vertical direction. Alternatively, the drain 14 may be coupled to the substrate and disposed adjacent to the substrate in the vertical direction. In certain aspects, a single material serves as both the drain 14 and the substrate.

A substrate may comprise a substrate material. Examples of suitable substrate materials include, but are not limited to, GaN, (Al,In,Ga)N, sapphire, silicon, silicon carbide, glass, polymers, metal, quartz, diamond, and the like.

In certain aspects, the substrate may have a thickness ranging from about 1 nm to about 2.0 mm. In aspects where the substrate is on the thin end of the aforementioned range, the substrate may be bonded to a carrier wafer. Without wishing to be bound by any particular theory, it is believed that substrates thicker than about 150 μm do not require bonding to a carrier wafer.

A current spreading layer 16 may be coupled to the drain 14 or the substrate and disposed adjacent to the respective drain 14 or substrate in the vertical direction.

The current spreading layer 16 may comprise a current spreading material. Examples of suitable current spreading material include, but are not limited to, n+ GaN, (Al,In,Ga)N, and the like.

In certain aspects, the current spreading layer 16 may have a thickness ranging from about 1 nm to about 2 mm.

The current spreading material may comprise a current spreading dopant. In certain aspects, the current spreading dopant may comprise silicon, oxygen, germanium, and the like. In certain aspects, the current spreading material may comprise current spreading dopant in an amount ranging from about 1×10¹⁷ cm⁻³ to about 5×10²⁰ cm⁻³. In certain aspects, the current spreading material may have an electron mobility ranging from about 10 cm²/V·s to about 1500 cm²/V·s.

A drift region may be coupled to the drain 14, the substrate, or the current spreading layer 16, and disposed adjacent to the respective drain 14, substrate, or current spreading layer 16 in the vertical direction.

The drift region may comprise a drift region material. Example of suitable drift region materials include, but are not limited to, n− GaN, n− (Al,Ga,In)N, and the like.

In certain aspects, the drift region may have a thickness of at least about 500 nm. Depending on the range of power and associated voltage required for the application, the thickness can be between 10 nm-10 μm (corresponding approximately to 3V-3000V).

The drift region material may comprise a drift region dopant. In certain aspects, the drift region dopant may comprise silicon, oxygen, germanium, and the like. In certain aspects, the drift region material may comprise drift region dopant in an amount ranging from about 1×10¹⁴ cm⁻³ to about 5×10¹⁷ cm⁻³. In certain aspects, the drift region material may have an electron mobility ranging from about 100 cm²/V·s to about 1500 cm²/V·s.

The semiconductor structures 10, devices 12, or III-nitride vertical transistors 12 may comprise one or more functional bilayers 20. The one or more functional bilayers 20 may be produced by a method that does not involve regrowth. Without wishing to be bound by any particular theory, it is believed that a regrowth process produces a physical difference at an interface when compared with a process that does not involve regrowth. Implantation processes are believed to damage the crystal structure and contaminate interfaces with impurities such as silicon. Performing Secondary Ion Mass Spectroscopy (SIMS) on material at the interface or taking a Transmission Electron Microscopy (TEM) image of a cross-section of the interface would identify the difference between an interface that was produced from a regrowth process and an interface that was not produced from a regrowth process. A person having ordinary skill in the art would be able to distinguish between an interface that was produced from a regrowth process and an interface that was not produced from a regrowth process.

In certain aspects, the functional bilayer 20 may have a thickness ranging from about 2 nm to about 20 nm.

Referring to FIG. 2, in certain aspects, the functional bilayer 20 may comprise a barrier layer 26 and a 2DEG-containing layer 28.

The barrier layer 26 may comprise a barrier material. The character of the barrier material may be impacted by the character of the materials immediately adjacent to the barrier material, in particular, the 2DEG-containing material. In other words, a barrier material may exhibit current blocking properties under some conditions and may lack current blocking properties under other conditions. Examples of suitable barrier materials include, but are not limited to, AlGaN, (Al,In,Ga)N, and the like.

The barrier layer 26 may comprise a current blocking layer and an aperture region. The channel in the aperture region may be formed by the presence of a trench, the application of a gate voltage in excess of a threshold voltage, or a combination thereof. In certain aspects, the aperture region may have an electron density ranging from about 1×10¹² cm⁻² to about 2.5×10¹³ cm⁻² when a gate voltage exceeds the threshold voltage. In certain aspects, the aperture region may have an electron mobility ranging from about 300 cm²/V·s to about 2200 cm²/V·s when a gate voltage exceeds the threshold voltage.

In certain aspects, the current blocking layer and aperture region are comprised of the same material. In preferred aspects, the current blocking layer and aperture region are formed by polarization engineering. In certain aspects, the current blocking layer and aperture region are not formed by doping or implantation. In preferred aspects, the current blocking layer and aperture region are not formed by a regrowth process.

In certain aspects, the barrier layer 26 may have a thickness ranging from about 1 nm to about 20 nm.

In certain aspects, the barrier layer 26 may have an electron density ranging from about 1×10¹³ cm⁻³ to about 1×10¹⁷ cm⁻³. In certain aspects, the barrier layer 26 may have an electron mobility ranging from about 10 cm²/V·s to about 2000 cm²/V·s.

Electrons may pass through the barrier layer 26 via tunneling.

In certain aspects, the 2DEG-containing layer 28 may comprise a 2DEG. The 2DEG may have an electron density ranging from about 1×10¹² cm⁻² to about 2.5×10¹³ cm⁻², or from about 5×10¹² cm⁻² to about 2×10¹³ cm⁻². The 2DEG may have an electron mobility ranging from about 300 cm²/V·s to about 2200 cm²/V·s.

The 2DEG-containing layer 28 may comprise a 2DEG-containing material. The character of the 2DEG-containing material and corresponding 2DEG may be impacted by the character of the materials immediately adjacent to the 2DEG-containing material, in particular, the barrier material. In other words, a 2DEG-containing material may contain a 2DEG under some conditions and may lack a 2DEG under other conditions. Examples of suitable 2DEG-containing materials include, but are not limited to, GaN, (Al,In,Ga)N, and the like.

In certain aspects, the 2DEG-containing layer 28 may have a thickness ranging from about 0.1 nm to about 10 nm. In certain aspects, the 2DEG-containing layer 28 contains the 2DEG, but is not comprised exclusively of the 2DEG. In certain aspects, the 2DEG-containing layer 28 consists of a material and a portion of that layer or material contains the 2DEG.

In preferred aspects, the functional bilayer 20 may comprise a barrier layer 26 that is an AlGaN layer and a 2DEG-containing layer 28 that is a GaN layer coupled to the AlGaN layer and disposed adjacent to the AlGaN layer along a vertical direction.

In certain aspects, the semiconductor structure 10, device 12, or III-nitride vertical transistor 12 may comprise one or more trenches. The trench or trenches may be formed by etching and may optionally be further processed to contain a gate 22 or SCFP. The trench or trenches may extend partially through the 2DEG-containing layer 28, fully through the 2DEG-containing layer 28, partially through the barrier layer 26, fully through the barrier layer 26, partially through the drift region, or a combination thereof. In certain aspects, the trench or trenches may have vertical side walls or tapering side walls.

The gate 22 may be positioned above or within the aperture region. In preferred aspects, the flow of electrons through the aperture may be modulated by the gate 22.

The gate 22 may comprise a gate material. In principle, any material that functions as a gate 22 is suitable for use in the present disclosure as a gate material. The gate material is preferably an electrical conductor. Examples of suitable gate materials include, but are not limited to, a metal (e.g., nickel, titanium, gold, copper, molybdenum, tungsten, tantalum, ruthenium, rhodium, palladium, platinum, etc.), a metal-containing compound (e.g., tantalum nitride, titanium nitride, etc.) polysilicon, polycrystalline silicon-germanium, and the like.

The gate 22 may have a portion within a trench having an aperture length (Lₐₚ) and a portion outside of the trench and located above the functional bilayer 20 having a full gate length (L_{g}).

The gate 22 may be placed on top of the aperture and have an aperture length ranging from about 0.1 μm to about 30 μm. The gate 22 may have a full gate length ranging from about 0.1 μm to about 50 μm.

The source 24 may be coupled to the 2DEG-containing layer 28. In preferred aspects, the source 24 may be coupled to the 2DEG.

The source 24 may comprise a source material. In principle, any material that functions as a source 24 is suitable for use in the present disclosure as a source material. The source material is preferably an electrical conductor. Examples of suitable source materials include, but are not limited to, silicon-, oxygen-, or germanium-doped or implanted regions of (Al,Ga,In)N, and the like.

The device 12 or III-nitride vertical transistor 12 may further comprise a drain contact coupled to the drain 14, a gate contact coupled to the gate 22, a source contact coupled to the source 24, or a combination thereof.

The drain contact may comprise a drain contact material. The gate contact may comprise a gate contact material. The source contact may comprise a source contact material. The drain contact material, gate contact material, or source contact material is preferably an electrical conductor. Examples of suitable drain, gate, or source contact materials include, but are not limited to, a metal (e.g., nickel, titanium, gold, copper, molybdenum, tungsten, tantalum, ruthenium, rhodium, palladium, platinum, etc.), a metal-containing compound (e.g., tantalum nitride, titanium nitride, etc.) polysilicon, polycrystalline silicon-germanium, silicide regions as is known in the art, combinations thereof, and the like.

The devices 12 and III-nitride vertical transistors 12 of the present disclosure may comprise a dielectric layer 30 adapted and positioned to provide electrical insulation between one or more of the gate 22, the SCFP, and the TCE and one or more of the functional bilayer 20, the 2DEG-containing layer 28, the barrier layer 26, and the drift layer 18.

In certain aspects, the device 12 or III-nitride vertical transistor 12 may be an enhancement mode (i.e., normally ON) or a depletion mode (i.e., normally OFF) device 12 or transistor 12.

There are 2 different modulation mechanisms that determine the normally-off or normally on operation of the device 12: 1) tunneling probability in the sidewall and the associated tunneling region overlapping the aperture region; and 2) the field-effect transport under the gate 22.

Normally off operation in these devices 12 can be ensured by appropriately choosing the layer thickness for the barrier layer 26 and 2DEG-containing layer 28. For example, making the 2DEG-containing layer 28 thinner (5 Å-2 nm) and the barrier layer 26 in the device 12 shown in FIG. 10 thicker (4 nm-15 nm). This will deplete the 2DEG under the gate 22 below the threshold voltage (>0V). The device 12 will conduct when the gates 22 are biased above the threshold voltage.

Normally ON: if the density of available states is increased in the sidewall region and the associated aperture region to ensure high tunneling probability at 0 V or lower bias voltages applied to gate, conduction could be achieved like in a normally ON operation device.

The number of states along the sidewall of the trenched region and associated tunneling region overlapping the aperture region can be controlled by selective implantation and/or doping of the region, or by biasing the TCE at a bias voltage >0 (separate from the gate biases) to ensure there is available states to favor tunneling.

The III-nitride materials of the present disclosure may be N-polar. Without wishing to be bound by any particular theory, it is believed that a functional bilayer 20 consisting of an N-polar AlGaN layer and an N-polar GaN layer coupled to the N-polar AlGaN layer and disposed adjacent to the N-polar AlGaN layer in the vertical direction will provide a barrier layer 26 within or coextensive with the N-polar AlGaN layer and a 2DEG within or coextensive with the N-polar GaN layer.

In certain aspects, the functional bilayer 20 may be grown in a single crystal growth process. In certain aspects, the drift layer 18 and functional bilayer 20 may be grown in a single crystal growth process. In certain aspects, the current spreading layer 16, drift layer 18, and functional bilayer 20 may be grown in a single crystal growth process. In preferred aspects, the drain 14, current spreading layer 16, drift layer 18, and functional bilayer 20 may be grown in a single crystal growth process.

The semiconductor structures 10, devices 12, and III-nitride vertical transistors 12 of the present disclosure may have a height in the vertical direction ranging from about 55 μm to about 2.0 mm. The semiconductor structures 10, devices 12, and III-nitride vertical transistors 12 of the present disclosure may have a length in a direction perpendicular to the vertical direction ranging from about 10.0 μm to about 100.0 μm. In certain aspects, the semiconductor structures 10, devices 12, and III-nitride vertical transistors 12 may be scaled to create a multiplexed system (for example, in a multiple finger geometry) having larger physical dimensions in a direction perpendicular to the vertical direction. In such aspects, the multiplexed system can have a length in a direction perpendicular to the vertical direction of up to about 10.0 mm.

The devices 12 and III-nitride vertical transistors 12 of the present disclosure may perform closer to an ideal switch than currently-available devices and transistors. In certain aspects, the devices 12 and III-nitride vertical transistors 12 may have a resistance in the OFF-state of at least 10 Ω/cm² or at least about 1000 Ω/cm². In certain aspects, the devices 12 and III-nitride vertical transistors 12 may have a resistance in the ON-state of at most about 10 mΩ/cm² or at most about 10 Ω/cm².

In certain aspects, the devices 12 and III-nitride vertical transistors 12 may have an On/Off current ratio ranging from about 10² to about 10¹⁰.

The devices 12 and III-nitride vertical transistors 12 of the present disclosure may have improved breakdown voltage when compared with conventional devices and transistors.

The devices 12 and III-nitride vertical transistors 12 of the present disclosure may have improved leakage current. In certain aspects, the devices 12 and III-nitride vertical transistors 12 may have a current density of less than about 0.4 A/cm² when the device or transistor is biased in the OFF state.

A person having ordinary skill in the art should appreciate that a threshold voltage can be determined using techniques known in the art. The threshold voltage may vary based on the thickness and composition of the layers of the devices 12 or III-nitride vertical transistors 12. The devices 12 and III-nitride vertical transistors 12 of the present disclosure may have a threshold voltage (Vₜ) of at least about 0.001 mV.

The semiconductor structures 10, devices 12, and III-nitride vertical transistors 12 of the present disclosure may exhibit nondispersive transport properties. In certain aspects, the drain 14, current spreading layer 16, drift layer 18, functional bilayer 20, 2DEG-containing layer 28, and barrier layer 26 may exhibit nondispersive transport properties.

This disclosure also provides methods of making a semiconductor structure 10, device 12, or III-nitride vertical transistor 12.

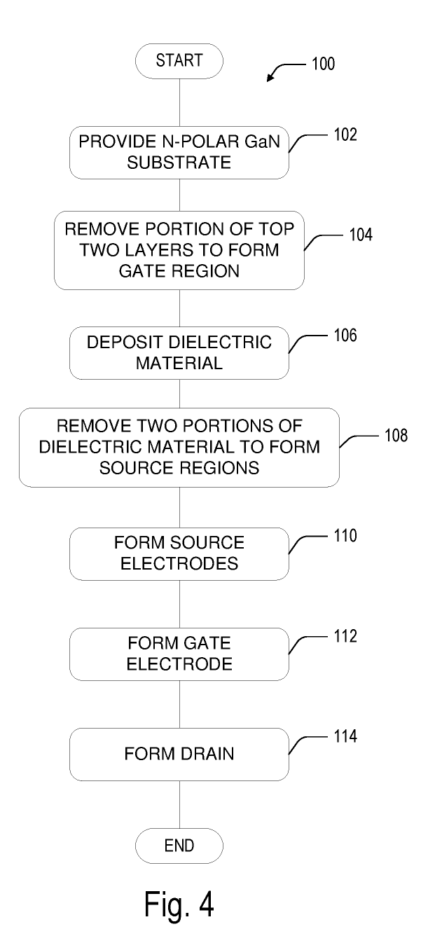

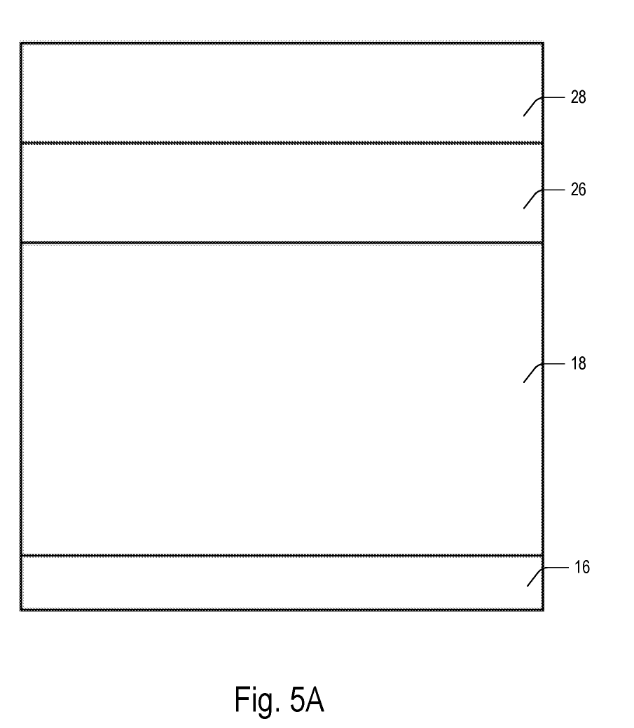

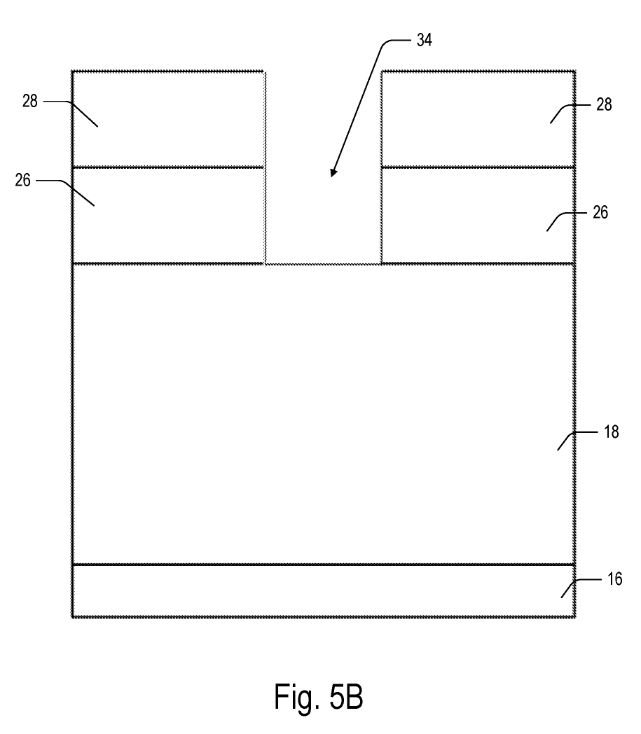

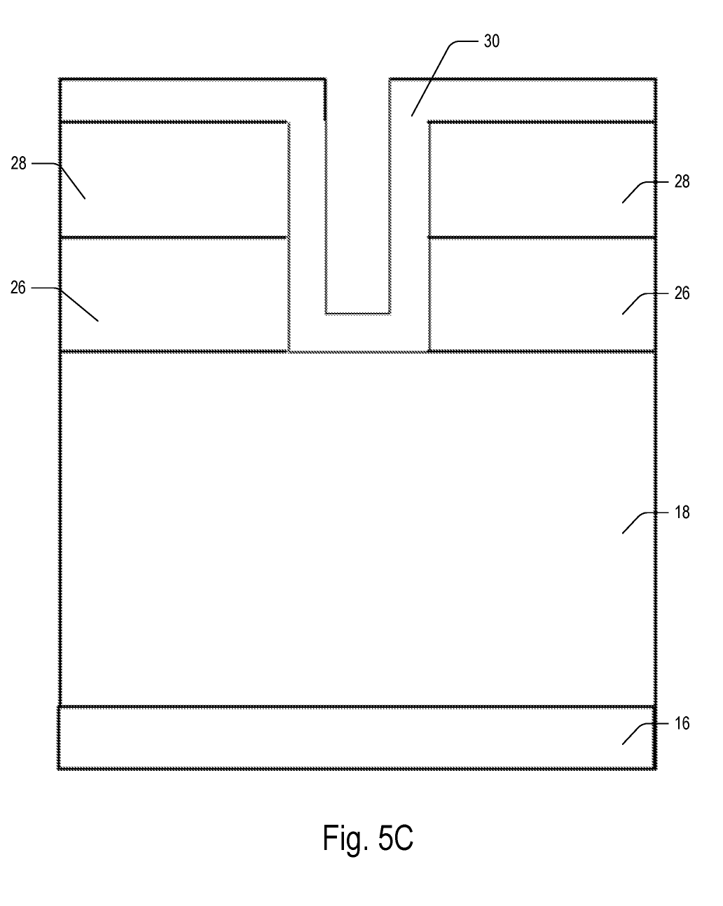

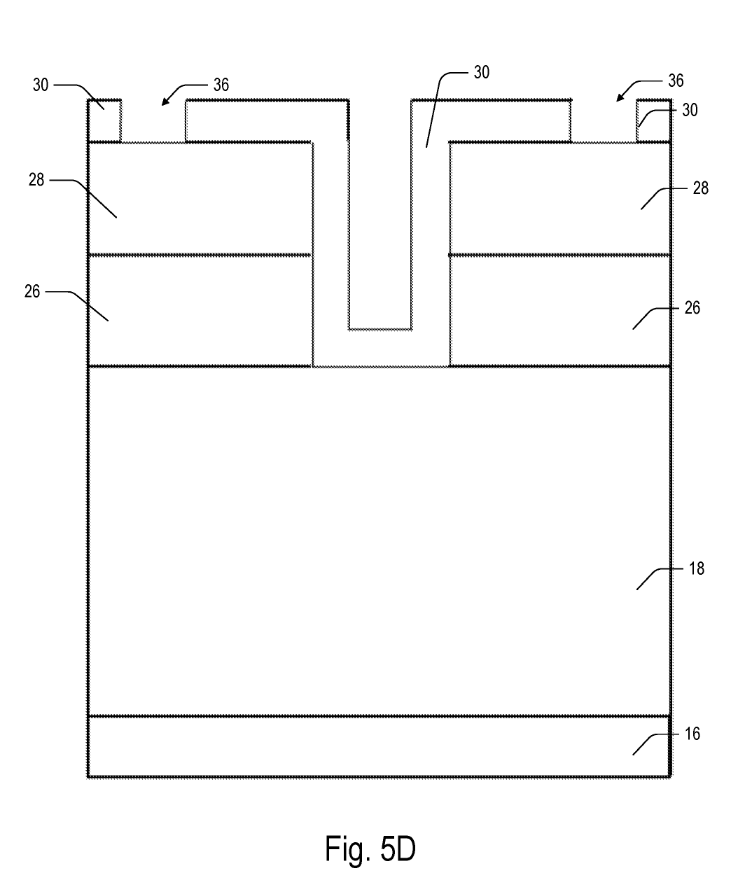

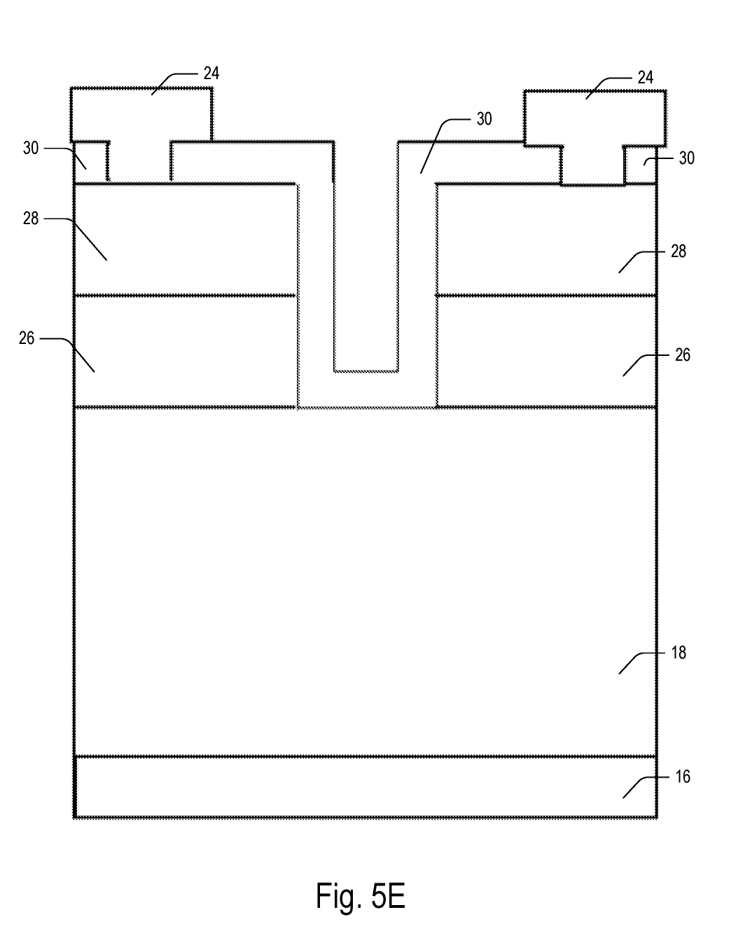

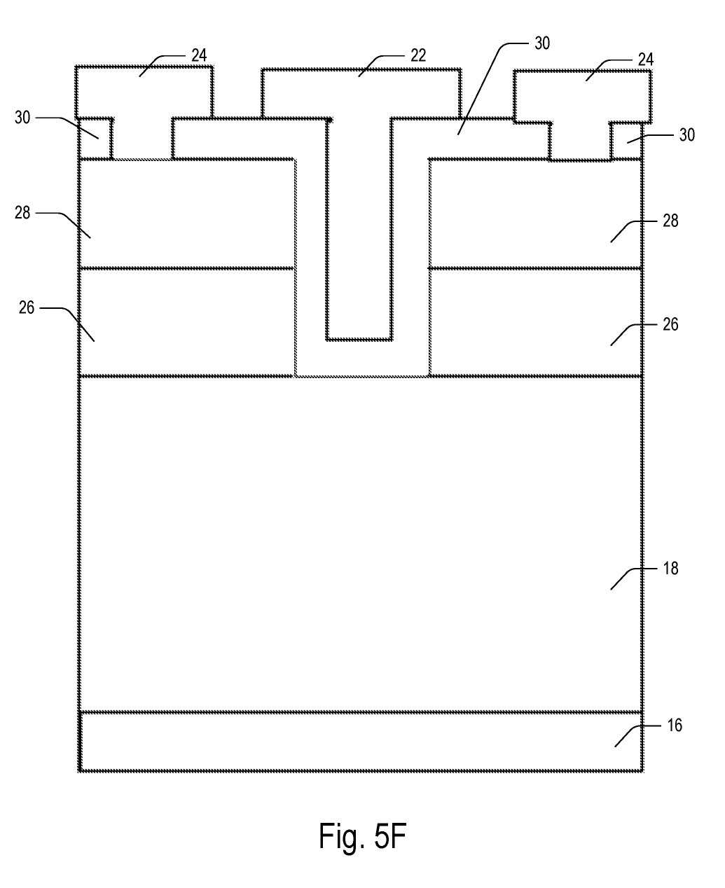

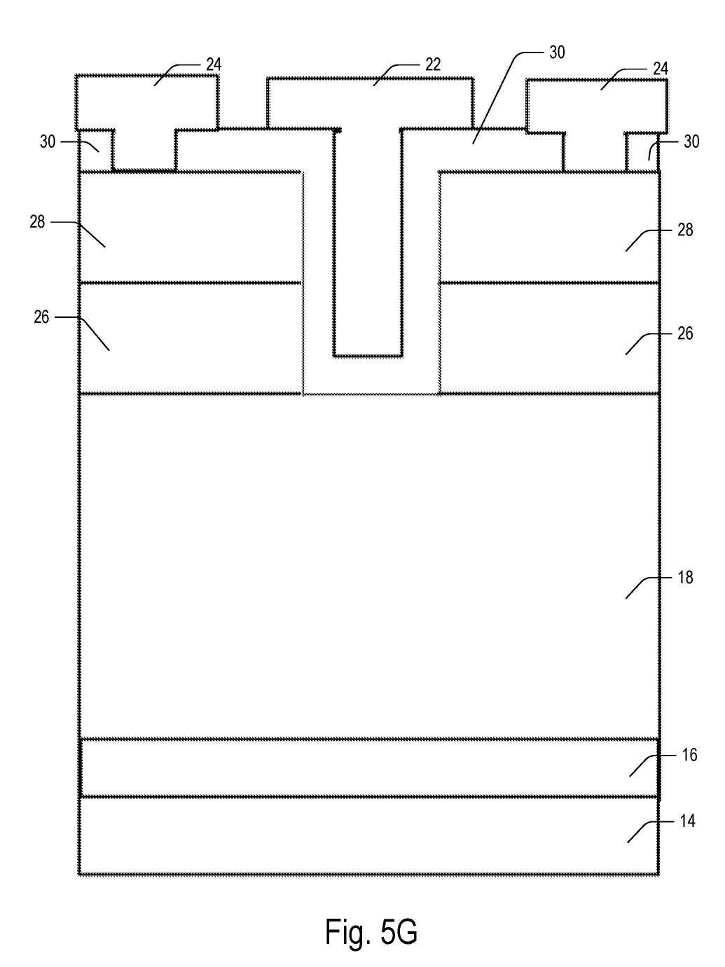

Referring to FIGS. 4 and 5a-5g, this disclosure provides a method 100 of making a device 12 or III-nitride vertical transistor 12. At process block 102, the method 100 can include providing an n-polar GaN substrate, such as the semiconductor structure 10 described herein. FIG. 5a is a schematic representation of the method 100 after process block 102. At process block 104, the method 100 can include removing a portion of the top two layers (i.e., the 2DEG-containing layer 28 and the barrier layer 26) to form a gate region 34. FIG. 5b is a schematic representation of the method 100 after process block 104. At process block 106, the method 100 can include depositing a dielectric material within the gate region 34, and optionally atop the 2DEG-containing layer 28 to form the dielectric layer 30. FIG. 5c is a schematic representation of the method 100 after process block 106. At process block 108, the method 100 can include removing two portions of the dielectric layer 30 to form source regions 36. FIG. 5d is a schematic representation of the method 100 after process block 108. At process block 110, the method 100 can include forming source electrodes 24 in the source regions 36 produced at process block 108. FIG. 5e is a schematic representation of the method 100 after process block 110. At process block 112, the method 100 can include forming a gate electrode 22 atop the dielectric material 30 in the gate region 34 formed at process blocks 104 and 106. FIG. 5f is a schematic representation of the method 100 after process block 112. At process block 114, the method 100 can include forming a drain electrode 14, optionally in ohmic contact with the current spreading layer 16. FIG. 5g is a schematic representation of the method 100 after process block 114.

The methods of the present disclosure may also include the following steps.

The methods may comprise obtaining, growing, or forming a substrate. The methods may comprise obtaining, growing, or forming a drain 14. In certain aspects, the methods may comprise growing or forming a drain 14 coupled to the substrate and disposed adjacent to the substrate in the vertical direction. In certain aspects, the methods may comprise growing or forming a substrate coupled to the drain 14 and disposed adjacent to the substrate in the vertical direction.

The methods may comprise obtaining, growing, or forming a current spreading layer 16. In aspects where the current spreading layer 16 is grown or formed, the methods may comprise growing or forming a current spreading layer 16 coupled to the drain 14 or substrate and disposed adjacent to the drain 14 or substrate in the vertical direction.

The methods may comprise obtaining, growing, or forming a drift layer 18. In aspects where the drift layer 18 is grown or formed, the methods may comprise growing or forming a drift layer 18 coupled to the current spreading layer 16 and disposed adjacent to the current spreading layer 16 in the vertical direction.

The methods may comprise obtaining, growing, or forming a functional bilayer 20. In aspects where the functional bilayer 20 is grown or formed, the methods may comprise growing or forming a functional bilayer 20 coupled to the drift layer 18 and disposed adjacent to the drift layer 18 in the vertical direction.

The methods may comprise obtaining, growing, or forming a barrier layer 26. In aspects where the barrier layer 26 is grown or formed, the methods may comprise growing or forming a barrier layer 26 coupled to the drift layer 18 and disposed adjacent to the drift layer 18 in the vertical direction.

The methods may comprise obtaining, growing, or forming a 2DEG-containing layer 28. In aspects where the 2DEG-containing layer 28 is grown or formed, the methods may comprise growing or forming a 2DEG-containing layer 28 coupled to the barrier layer 26 and disposed adjacent to the barrier layer 26 in the vertical direction.

The methods may comprise forming a gate region 34 or trench. The purpose of the trench may be to contain a gate 22 or a SCFP. Forming the trench may comprise etching or other processes that produce the same result as etching. In certain aspects, the gate region 34 or trench extends throughout the 2DEG-containing layer 28 and the barrier layer 26 to expose the drift layer 18.

The methods may comprise depositing a dielectric material to the interior of the trench, and optionally to the top surface of the functional bilayer 20.

The methods may comprise growing or forming a gate 22 or SCFP, optionally in the trench, and optionally on the top surface of the functional bilayer 20.

The methods may comprise growing or forming a source 24 coupled to the 2DEG-containing layer 28, and optionally coupled to the 2DEG. Forming the source 24 can be achieved by methods known to those having ordinary skill in the art. For example, a source metal can be deposited in the source regions 36, followed by an annealing step, for example, at about 900° C. for 30 seconds. As another example, Si implantation can be performed within the 2DEG-containing layer 28 beneath the source regions 36, followed by deposition of source contacts atop the Si-implanted regions. As yet another example, the 2DEG containing layer 28 can be etched beneath the source regions 36, and n+GaN can be regrown in the etched region, followed by deposition of source contacts atop the regrown n+GaN. It should be appreciated that the particular way that the source contacts are form is not intended to be limiting to the present disclosure, and any satisfactory process that forms the desired ohmic contact can be used.

Obtaining, growing or forming may comprise molecular beam epitaxy (MBE), chemical vapor deposition (CVD), metal organic CVD (MOCVD), hydride vapor pressure epitaxy (HVPE), or combinations thereof. Obtaining may further comprise simply acquiring the target of the obtaining step. An example of obtaining includes, but is not limited to, purchasing from a vendor.

In certain aspects, the method may not include a regrowth step. In certain aspects, the method may include regrowth steps in the forming of ohmic contact, but otherwise may not include a regrowth step. In certain aspects, the obtaining, growing, or forming a barrier layer may not include a regrowth step.

This disclosure also provides uses of the semiconductor structures 10, devices 12, and III-nitride vertical transistors 12 described herein. Examples of uses include, but are not limited to, use as a switch in an electronic application, in particular, in medium- and high-power (including, but not limited to 10 W-100 kW) electronic applications, in DC to DC, DC to AC, AC to DC, and AC to AC power converters, and the like. It should be appreciated that the semiconductor structures 10, devices 12, and III-nitride vertical transistors 12 of this disclosure are also suitable for low-power electronic applications, such as use in an S-band device, a radio-frequency device, or a combination thereof.

The present disclosure includes an active buried current blocking layer and aperture that can be grown in situ and formed by polarization manipulation without the need of a regrowth process. This represents a significant improvement over the prior art.

Vertical GaN transistors, CAVETs, LC-VJFETs, VMOSFETs, and other similar structures can include an n-type drift region to hold the voltage, a horizontal channel to carry electrons flowing from the source horizontally under a planar gate, and an aperture through which electrons flow vertically. In some existing technology, the aperture was first defined by MOCVD growth, and then the CBL was defined by implantation or regrowth. However, neither regrown CBL nor implanted CBL can hold a high voltage when compared with a CBL that is achieved by doping in situ during growth in a MOCVD reactor. According to one aspect, the present disclosure provides systems and methods for achieving the CBL by doping in sity during growth by MOCVD and forming an aperture region by ion implantation to selectively compensate for the acceptor in the CBL in the aperture region. Aperture region ion implantation can enable an in situ doped CBL, which can have better current blocking capabilities, thus enabling methods of regrowth free GaN vertical transistors, such as CAVET, LC-VJFET, and VMOSFET.

This disclosure provides a method including implanting Si, O, or H into an aperture region in a current blocking layer (CBL). The CBL can be exposed or buried during the implanting. Following the implanting, two annealing steps can be performed. A first high-temperature annealing can be performed to remove implantation-induced damage and electrically reactivate the material. A second annealing can reactivate the buried CBL by way of a via. The second annealing can be performed in the absence of hydrogen. The second annealing can be performed at a temperature above 700° C.

This disclosure also provides a method including implanting Si into portions of the CBL outside the aperture region. An additional high-temperature annealing can be performed to remove implantation-induced damage and electrically reactivate the material. The implanted portions can be used as source regions and source ohmic contacts can be electrically connected to the source regions.

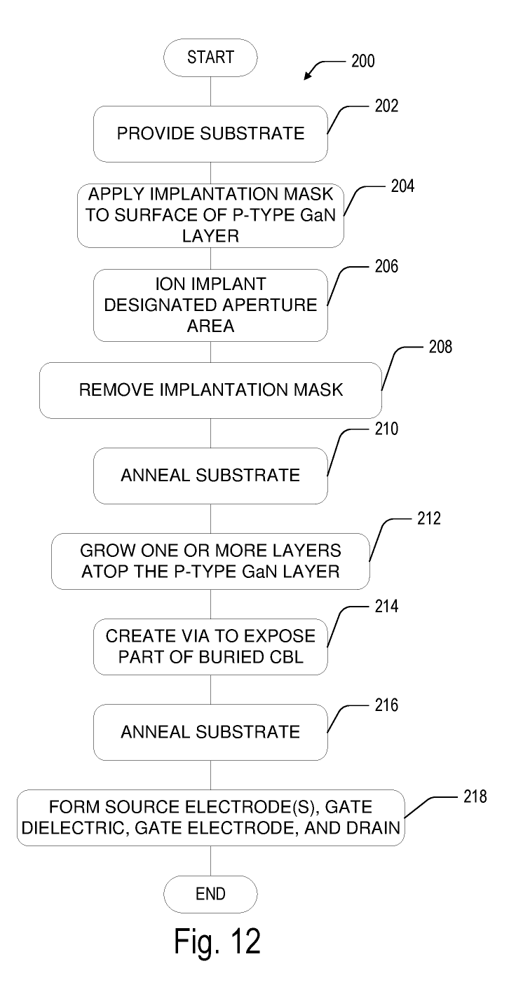

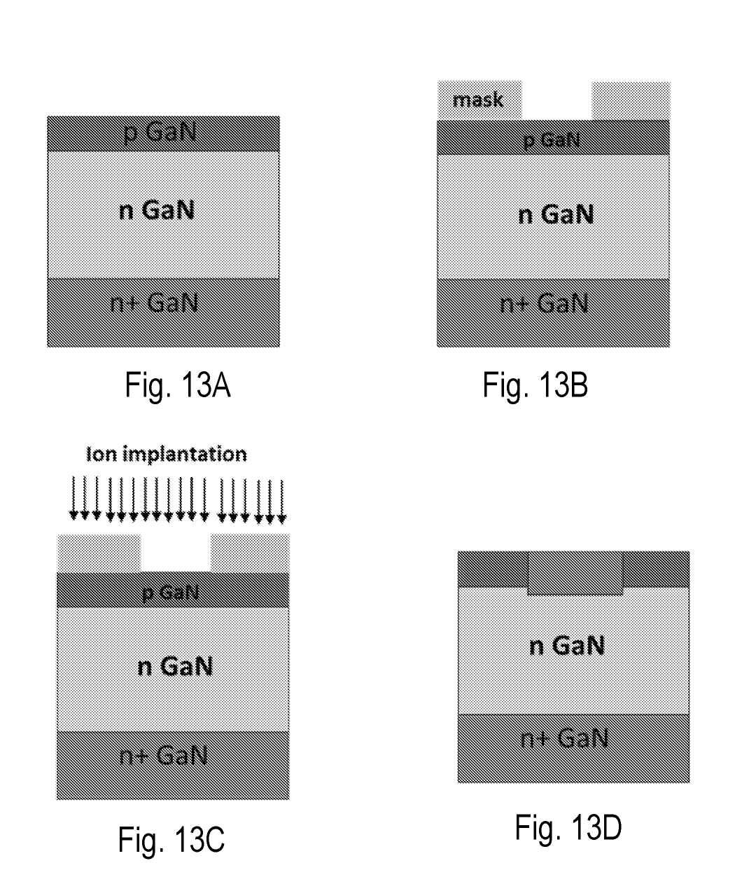

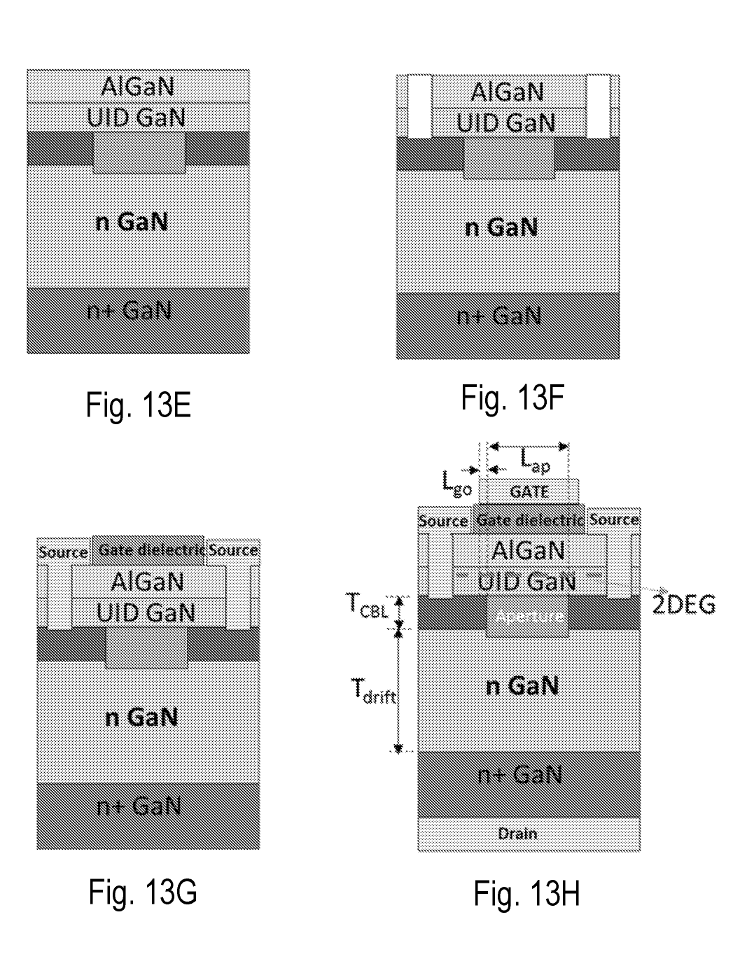

Referring to FIGS. 12 and 13a-h, this disclosure provides a method 200 of making a device 12 or III-nitride current aperture vertical electron transistor 12. At process block 202, the method 200 can include providing a substrate, such as the GaN MOCVD epitaxy layers illustrated in FIG. 13a, which can be grown on substrates including, but not limited to, GaN, SiC, Sapphire, Si, or the like. The GaN MOCVD epitaxy layers can include a thick n-type GaN or unintentionally doped (UID) GaN with low doping density (≤1×10¹⁶ cm⁻³) grown on a heavily doped n+ GaN and a p-type GaN, optionally Mg-doped, which is grown on top of the drift region. Part of the p-type GaN can serve as the CBL. The CBL is exposed to the atmosphere.

At process block 204, the method 200 can include applying an implantation mask to the surface of the p-type GaN layer. The implantation mask can define a designated aperture area in the CBL. The mask can be a metal mask, a dielectric mask, a photoresist mask, or the like. FIG. 13b is a schematic representation of the method 200 after process block 204.

At process block 206, the method 200 can include ion implanting the designated aperture area. The ion implanting can provide a well-defined impurity concentration in regions not covered by the implantation mask (i.e., the designated aperture area). In certain aspects, the ion implanting can utilize multiple energies in order to form a box profile donor concentration. FIG. 13c is a schematic representation of the method 200 during process block 206.

At process block 208, the method 200 can include removing the implantation mask. The implantation mask can be removed by methods known to those having ordinary skill in the art. At process block 210, the method 200 can include annealing the substrate. The annealing can be a high temperature annealing. The annealing can remove the implantation-induced damage and to enable the material to become electrically active. The annealing temperature is dependent on the properties of the implanted material, as will be appreciated by a person having ordinary skill in the art. As one example, the annealing temperature for Si implantation can be about 1280° C. FIG. 13d is a schematic representation of the method 200 after process blocks 208 and 210.

At process block 212, the method 200 can include growing one or more layers atop the p-type GaN layer including the aperture region. The one or two layers can include two III-nitride layers. The two III-nitride layers can form a lateral channel to carry current flow horizontally. The two layers can be formed of materials capable of forming a 2DEG, such as an AlGaN/GaN bilayer, where the 2DEG is located at the AlGaN/GaN interface. The two layers can also be formed of materials capable of forming a junction gate field-effect transistor (JFET) lateral channel, such as a p-GaN/n-GaN bilayer. FIG. 13e is a schematic representation of the method 200 after process block 212.

At process block 214, the method 200 can include creating a via, for example by etching, to expose part of the buried CBL to expose that part to the atmosphere. At process block 216, the method 200 can include annealing to cause a reaction in the buried p-type GaN CBL. The annealing of process block 216 can be at a temperature above 700° C. FIG. 13f is a schematic representation of the method 200 after process blocks 214 and 216.

At process block 218, the method 200 can include forming one or more source electrodes, a gate dielectric, a gate electrode, and a drain. The one or more source electrodes can be formed by alloyed contact or non-alloyed contact with source area implantation. The alloyed contact can be formed by Ti/Al or Ti/Al/Ni/Au with an annealing at a temperature of above 800° C. The non-alloyed contact with source implantation can be performed using Si implantation. FIG. 13g is a schematic representation of the method 200 after forming the one or more source electrodes and the gate dielectric, but prior to forming the gate electrode and the drain. FIG. 13h is a schematic representation of the complete device after the method 200 is complete.

Referring to FIG. 13h, the resulting GaN CAVET can include a thick drift region to hold the off-state voltage. A CBL can be used to prevent current flow from drain to source without modulating the gate. The aperture region can be used to carry the vertical current flow, and the AlGaN/GaN layers can be used to form a lateral channel to carry the current flow horizontally.

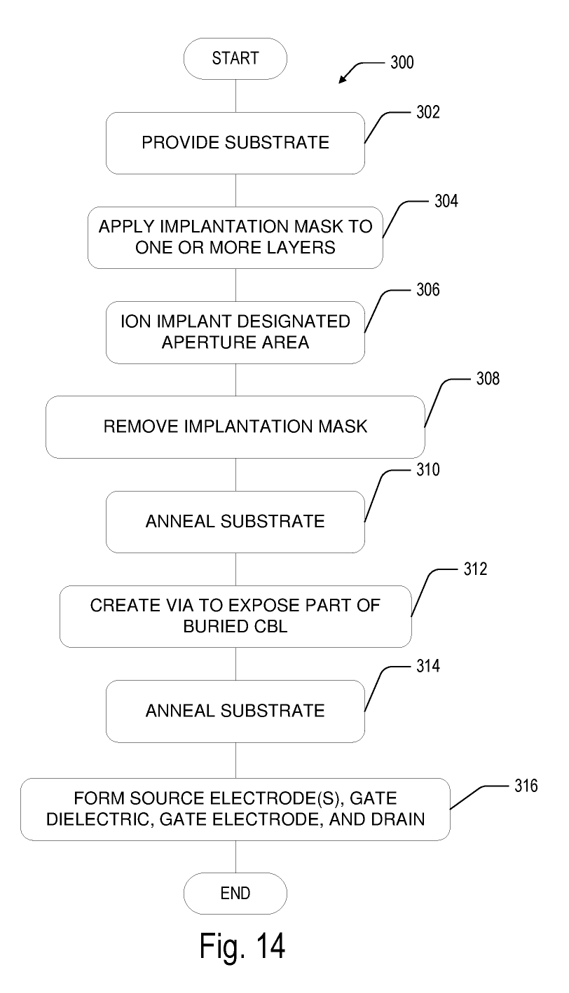

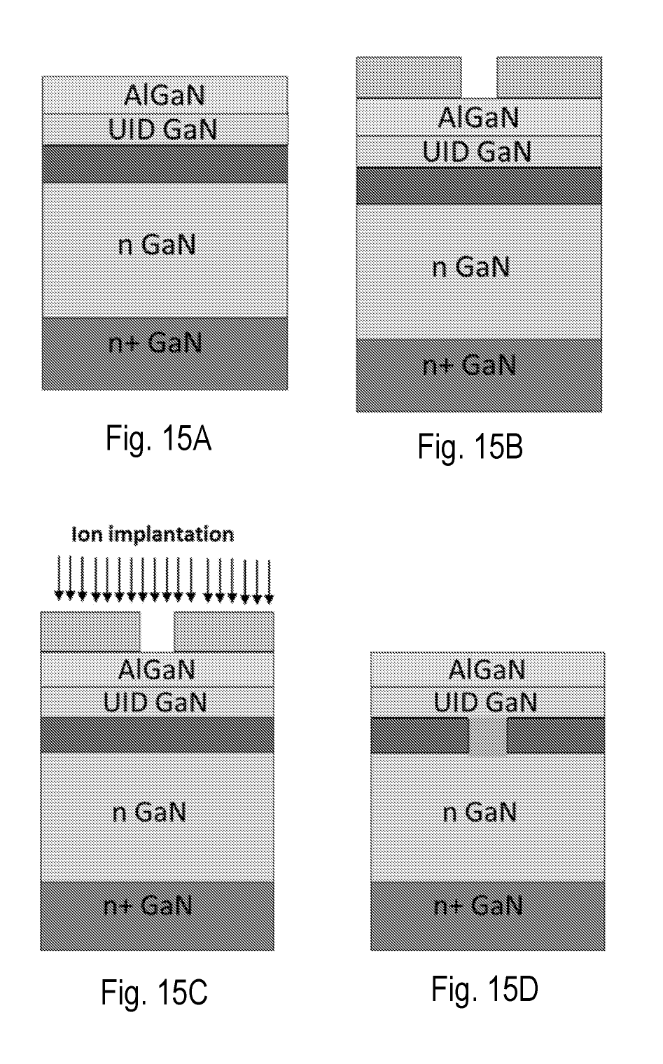

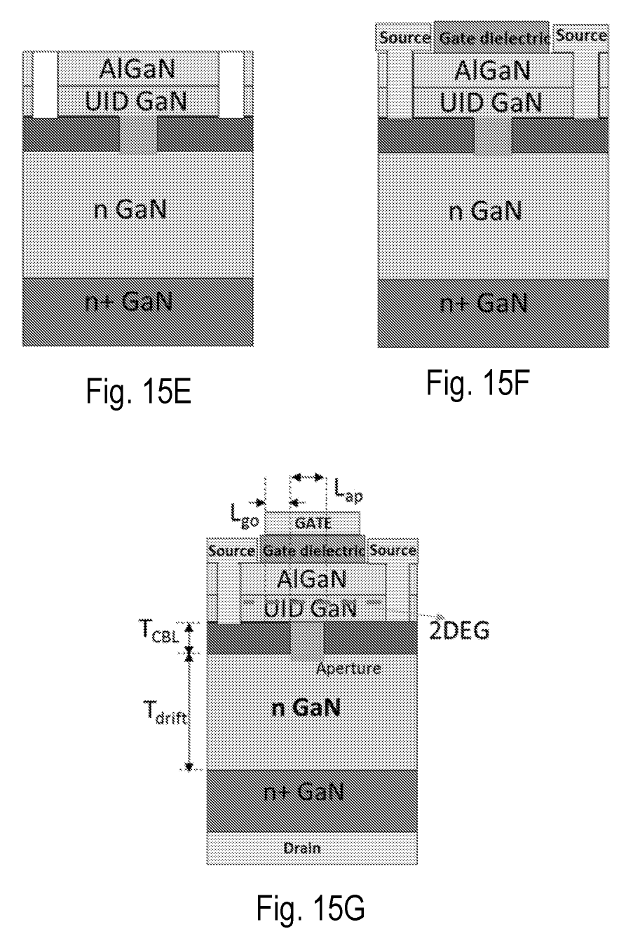

Referring to FIGS. 14 and 15a-g, this disclosure provides a method 300 of making a device 12 or III-nitride current aperture vertical electron transistor 12. At process block 302, the method 300 can include providing a substrate, such as the GaN MOCVD epitaxy layers illustrated in FIG. 15a, which can be grown on substrates including, but not limited to, GaN, SiC, Sapphire, Si, or the like. The substrate can be formed by methods described elsewhere herein and can include layer materials and properties described elsewhere herein. As can be seen FIG. 15a, in contrast to the method 200, the CBL is buried. The CBL is located beneath one or more layers, such as one or two III-nitride layers, the one or more layers including a lateral channel to carry current flow horizontally. The one or more layers can have properties such as those described elsewhere herein, such as the one or more layers grown in process block 212 of method 200.

At process block 304, the method 300 can include applying an implantation mask to the surface of the one or more layers. The implantation mask can define a designated aperture area in the CBL. The mask can have properties described elsewhere herein. FIG. 15b is a schematic representation of the method 300 after process block 304.

At process block 306, the method 300 can include ion implanting the designated aperture area. The ion implanting can have similar properties as the ion implanting in the method 200. FIG. 15c is a schematic representation of the method 300 during process block 306.

At process block 308, the method 300 can include removing the implantation mask. At process block 310, the method 300 can include annealing the substrate. The annealing can have properties similar to those described with respect to method 200. FIG. 15d is a schematic representation of the method 300 after process blocks 308 and 310. At process block 312, the method 300 can include creating a via, for example by etching, to expose part of the buried CBL to expose that part to the atmosphere. At process block 314, the method 300 can include annealing to cause a reaction in the buried p-type GaN CBL. The annealing of process block 314 can be at a temperature above 700° C. FIG. 15e is a schematic representation of the method 300 after process blocks 312 and 314. At process block 316, the method 300 can include forming one or more source electrodes, a gate dielectric, a gate electrode, and a drain. The forming of process block 316 can have properties such as the forming of process block 218 of method 200. FIG. 15f is a schematic representation of the method 300 after forming the one or more source electrodes and the gate dielectric, but prior to forming the gate electrode and the drain. FIG. 15g is a schematic representation of the complete device after the method 300 is complete.

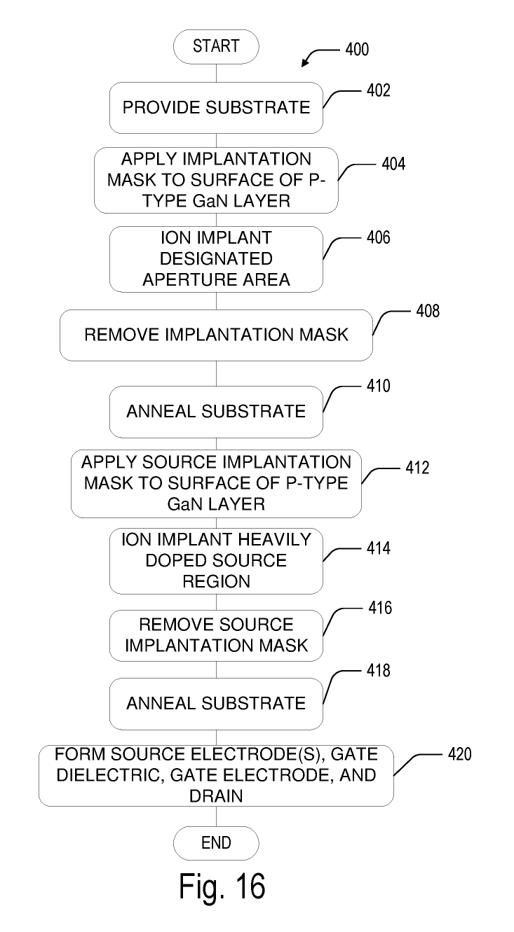

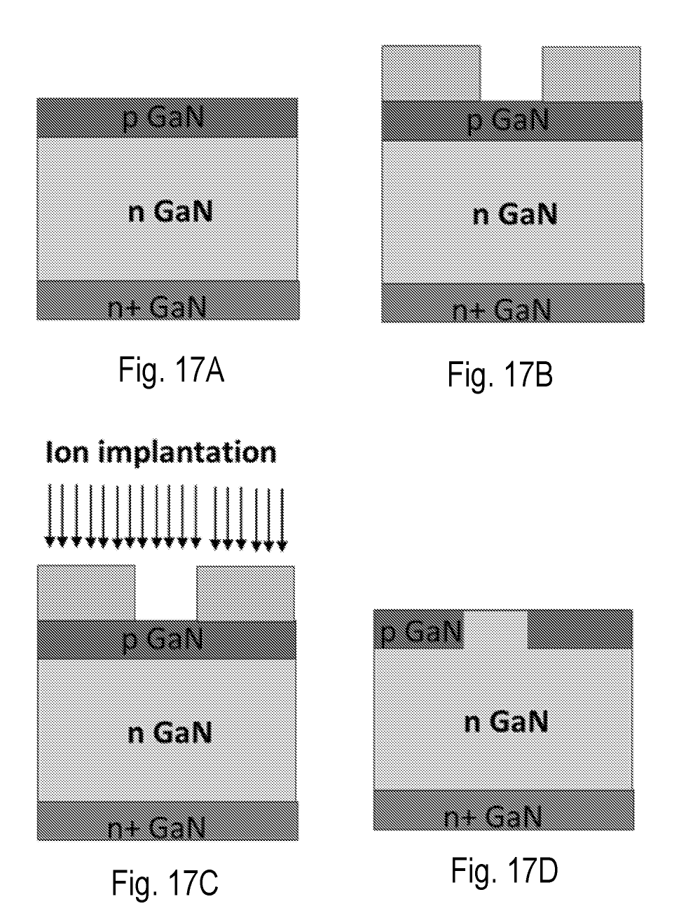

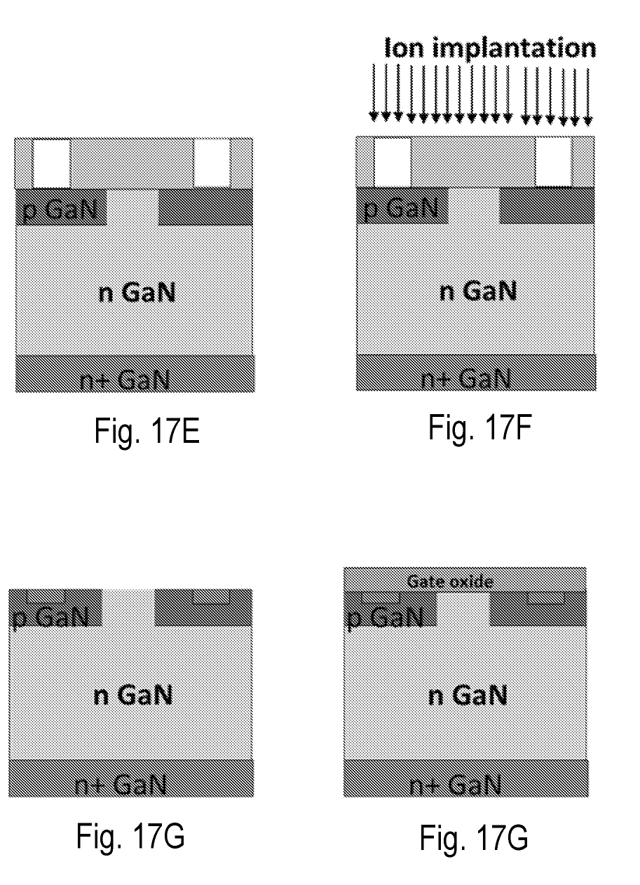

Referring to FIGS. 16 and 17a-i, this disclosure provides a method 400 of making a device 12 or III-nitride metal-oxide-semiconductor field-effect transistor 12. Process blocks 402, 404, 406, 408, and 410 are substantially similar to process blocks 202, 204, 206, 208, and 210. FIGS. 17a, 17b, and 17d are schematic representations of the method 400 after process blocks 402, 404, and 410, respectively, and FIG. 17c is a schematic representation of the method 400 during process block 406.

At process block 412, the method 400 can include applying a source implantation mask to the surface of the p-type GaN layer. The source implantation mask can define a heavily doped source region of the CBL. The mask can have the properties described elsewhere herein. FIG. 17e is a schematic representation of the method 400 after process block 412.

At process block 414, the method 400 can include ion implanting the heavily doped source region of the CBL. The ion implanting can have the properties described elsewhere herein. FIG. 17f is a schematic representation of the method 400 during process block 414. At process block 416, the method 400 can include removing the source implantation mask. At process block 418, the method 400 can include high-temperature annealing the substrate. FIG. 17g is a schematic representation of the method 400 after process blocks 416 and 418. At process block 420, the method 400 can include forming one or more source electrodes, a gate dielectric, a gate electrode, and a drain. The forming of process block 420 can have properties such as those described elsewhere herein. FIG. 17h is a schematic representation of the method after the forming a gate dielectric layer of process block 420, but before forming the source electrodes, gate electrode, and drain. FIG. 17i is a schematic representation of the complete device after the method 400 is complete.

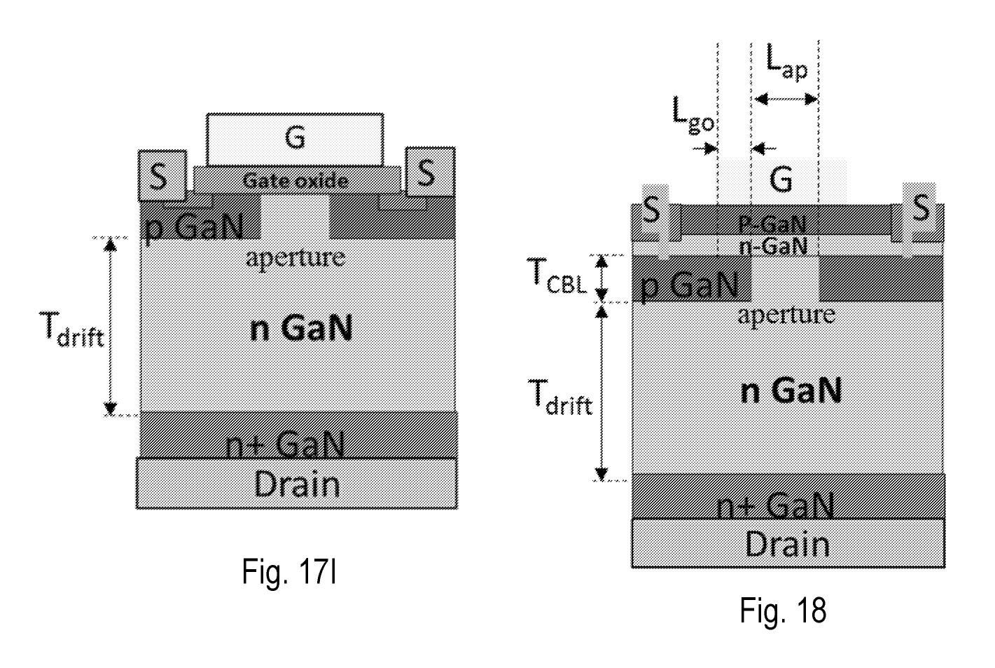

Referring to FIG. 18, a lateral channel vertical junction field-effect transistor (LC-VJFET) is schematically shown. The LC-VJFET can include a thick n-GaN drift region with a UID GaN. The LC-VJFET can include a p-type GaN with doped acceptors to block current flow through any path other than the n-type aperture region. The channel layer can be formed by epitaxy grown n-GaN. The gate metal can be connected to the top p-GaN layer forming ohmic contact. The source region can be formed by implantation. The entire structure can be epitaxially grown on different substrates, such as Si, SiC, Sapphire, or III-nitride. The methods 200, 300 can be used to form the LC-VJFET of FIG. 18.

The methods 100, 200, 300, 400 can each include one or more steps disclosed in the other methods, can exclude one or more steps disclosed, can include features described with respect to the systems, and can include other processing steps known to those having ordinary skill in the art. The materials illustrated in the various Figs. showing the progression of the methods 200, 300, 400 are exemplary only and can be replaced with other materials that allow the same function, as can be appreciated by a person having ordinary skill in the art, including but not limited to, materials described elsewhere herein.

The present disclosure can be further understood by way of the following non-limiting examples.

### EXAMPLES

### Example 1

### Enhancement Mode, Low R_{ON} III-Nitride Vertical Transistor

A computer simulation was performed to simulate the performance of a GaN-based enhancement mode (i.e., normally off), low R_{ON} N-polar vertical device as shown in FIG. 2, produced with a regrowth free fabrication technique. The device consists of a high-electron density (˜1×10¹³/cm²), high mobility (˜1500 cm²/V·s) channel in the access region extending from the source to the gate sitting on a 3 nm-thick SiN. The SiN was deposited in situ on 2 nm-thick GaN. The GaN was deposited in situ on top of 4 nm-thick Al_{0.3}Ga_{0.7}N. The electrons were shown to tunnel from the source into region B and flow through the drift region into the drain. The region B was formed by etching away the GaN and the AlGaN layers from the top. The gate material in the region B sits on a dielectric layer, comprised of SiN, and thereby forms the normally-off part of the channel. A person having ordinary skill in the art should appreciate that the functionality of this device was achieved by polarization engineering and not by way of doping or implantation. As a result, the fabrication of this device can be achieved in a single growth process, which maintains the as-grown material quality throughout the fabrication process. The breakdown field in these devices is expected to be close to the theoretical predicted values since the material quality in the CBL was not compromised.

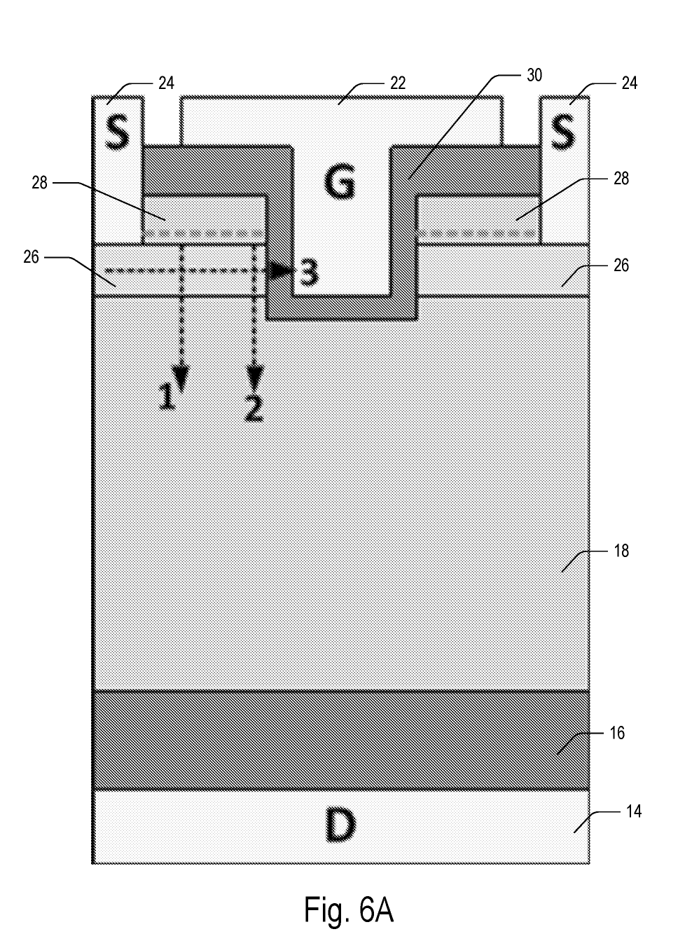

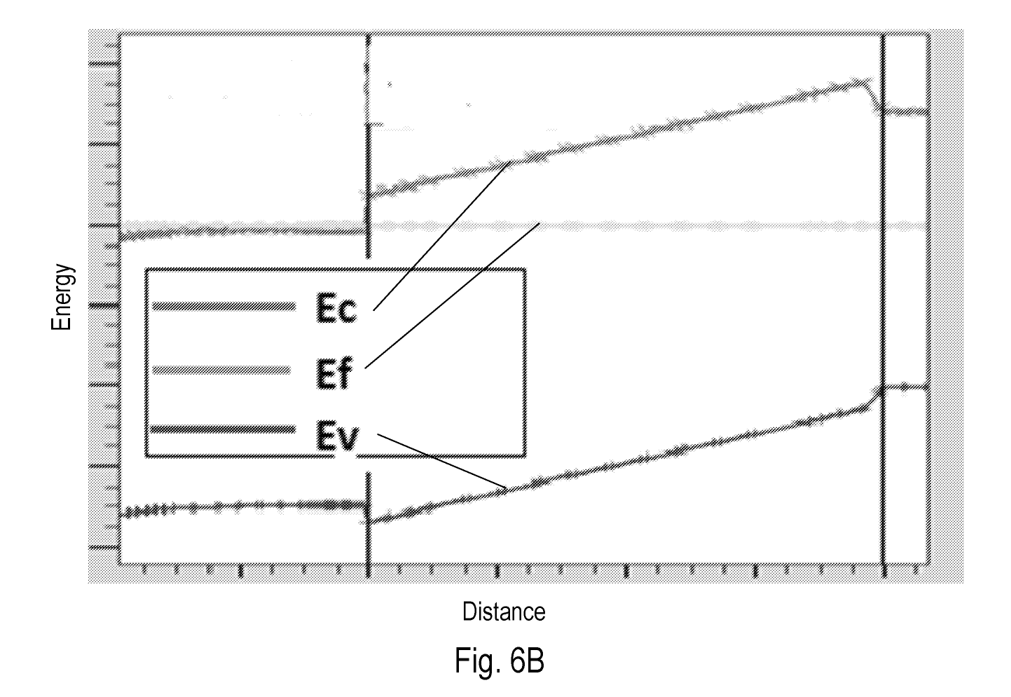

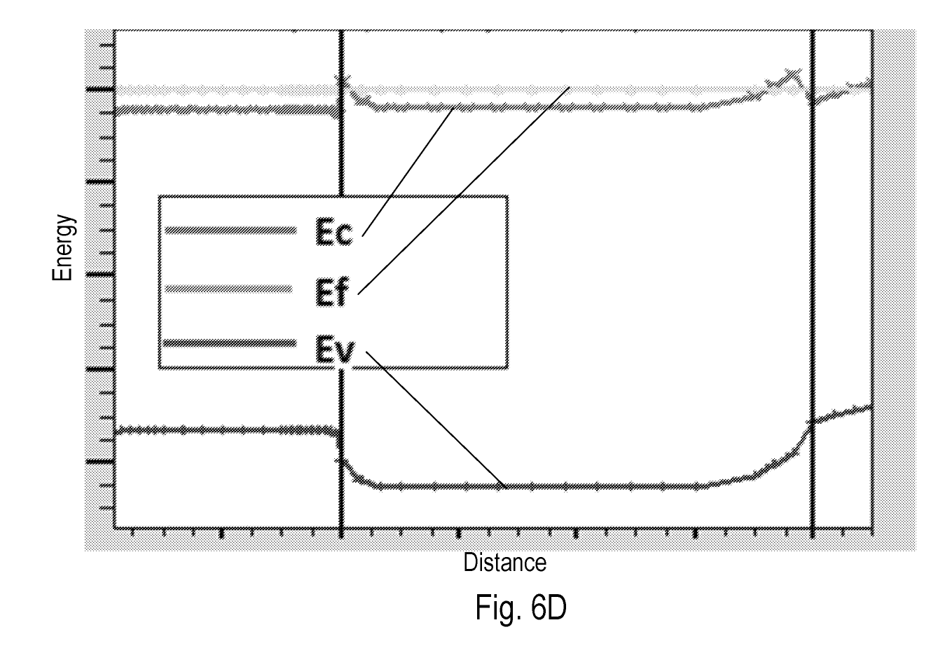

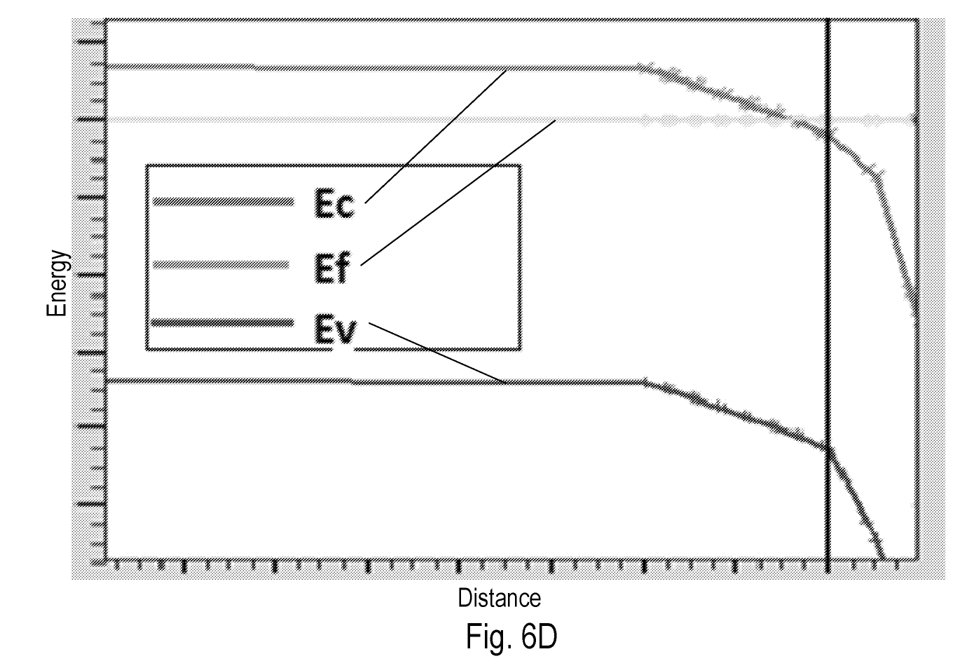

FIG. 6a shows a schematic of the device, with three routes identified. The energy band diagrams of the three routes are shown in FIGS. 3b, 3c, and 3d for a gate bias of 5 V. The x-axis is the distance along the respective route and the y-axis is the energy. The energy band diagram of route 1 (FIG. 6b) shows that a barrier exists at route 1, and therefore current will not flow along that path. The energy band diagram of route 2 (FIG. 6c) shows that a tunneling path is available at route 2, and therefore current could flow along that path. The energy band diagram of route 3 (FIG. 6d) shows that the gate bias induces energy band bending, which contributes to the presence of the tunneling path at route 2. The 2DEG density of this configuration can be as high as 4×10¹³ cm².

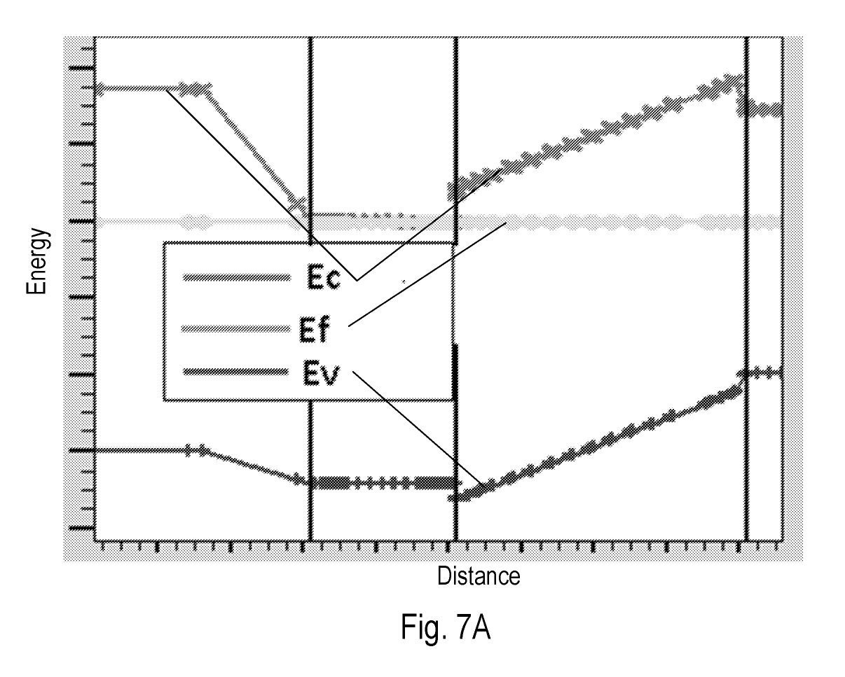

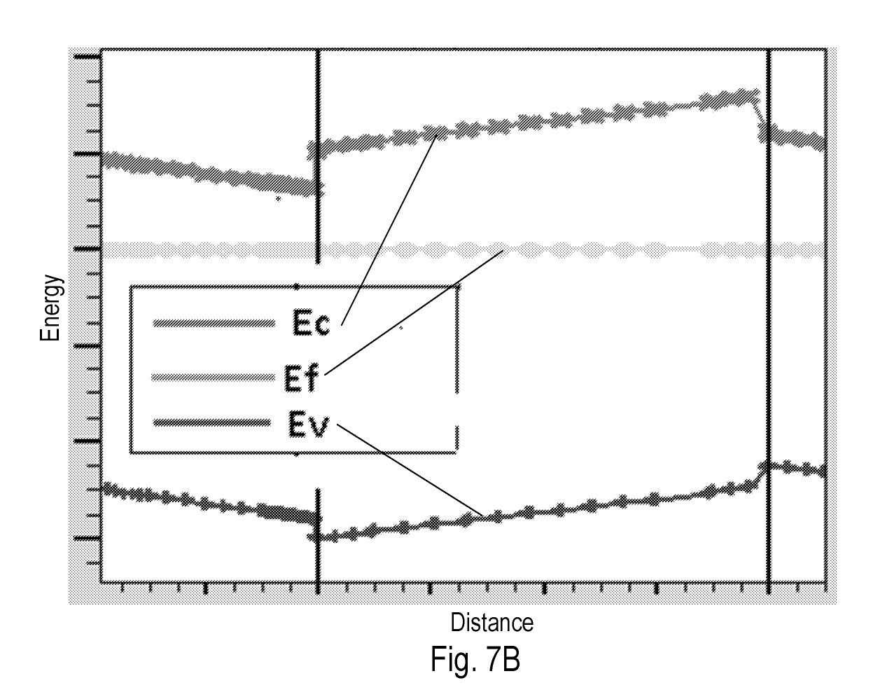

The energy band diagrams of routes 1 and 2 of FIG. 6a with a gate bias of 0 V are shown in FIGS. 7a and 7b, respectively. The x-axis is the distance along the respective route and the y-axis is the energy. The energy band diagrams of routes 1 and 2 show that a barrier exists at routes 1 and 2, and therefore current is inhibited from flowing along those paths. The 2DEG density of this configuration was approximately 7.5×10¹¹ cm².

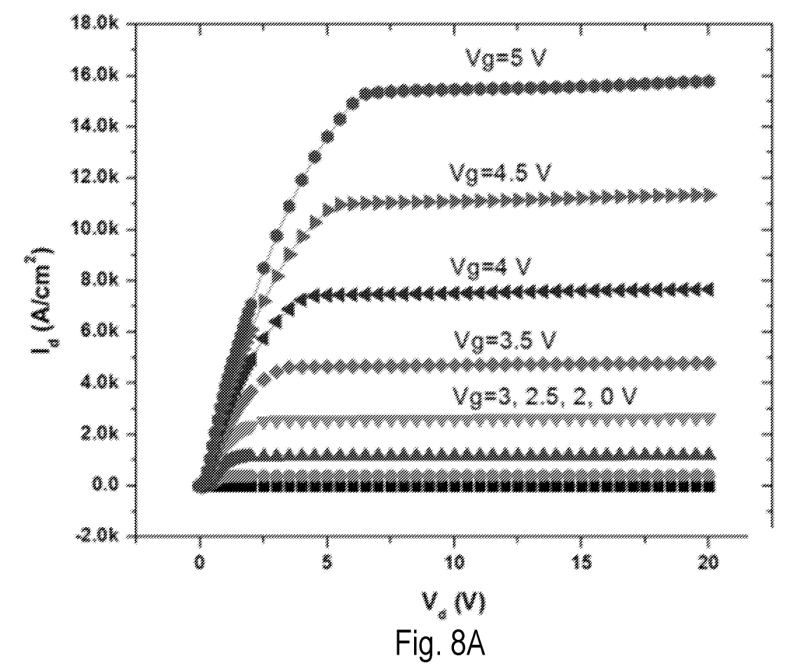

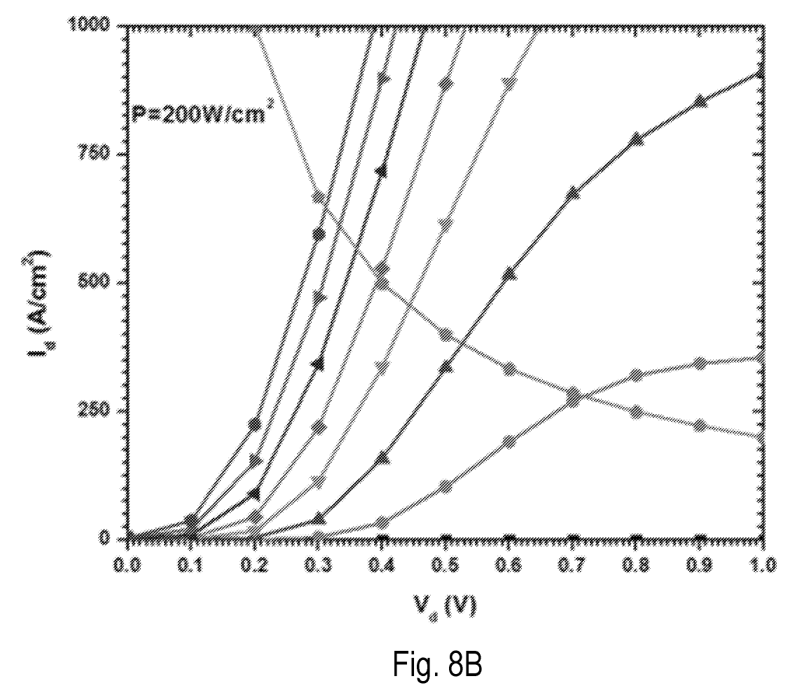

FIGS. 8a and 8b are plots of the I_{d}-V_{d} curve for the device at varying gate voltages. The plot in FIG. 8a is a zoomed-out view and shows that increasing gate voltages increases the maximum current. The plot in FIG. 8b is a zoomed in view and shows that the device exhibits diode-like behavior, which based on the understanding that transistors typically exhibit linear behavior, serves as evidence that tunneling is taking place.

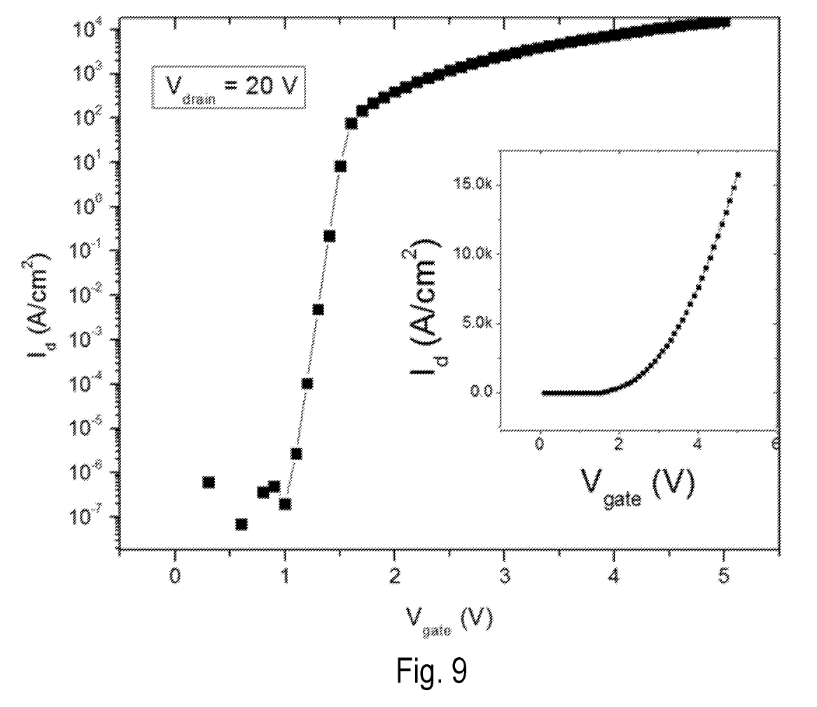

FIG. 9 is a plot of the I_{d}-V_{g} curve for the device on a logarithmic scale (main) and linear scale (inset). The plot shows that the threshold voltage (Vₜ) is greater than about 1 V and the current that passes in the OFF state is on the order of 10⁻⁶ A/cm².

### Example 2

### A Two-Channel Depletion Mode III-Nitride Vertical Transistor

A computer simulation was performed to simulate the performance of a two-channel depletion mode (i.e., normally on) device shown in FIG. 10 (right) with the semiconductor structure shown in FIG. 10 (left). This device consists of a high electron density (˜1.8×10¹³/cm²), high mobility (˜1500 cm²/V·s) channel in the access region extending from the source, where the electrons tunnel into the second channel under the secondary electrode, which is embodied by a source connected field plate (SCFP). The channel under the SCFP is formed by appropriately etching away the top channel region and the electron depleting top AlGaN layer, and then depositing a dielectric layer, such as SiN. The planar gates flank the aperture on both sides with a gate length of L_{GO} as shown in FIG. 10. In the ON-state of operation, the gate bias maximizes the conductance of the region beneath the gate. Electrons flow from the source through the access region and under the gates (L_{GO}). The electrons then tunnel into the second channel under the SCFP. The SCFP also provides a surface for termination of the electric field emanating from the channel and drift region below. The electrons tunnel through the thin AlGaN back barrier and subsequently flow into the drift region leading to the drain.

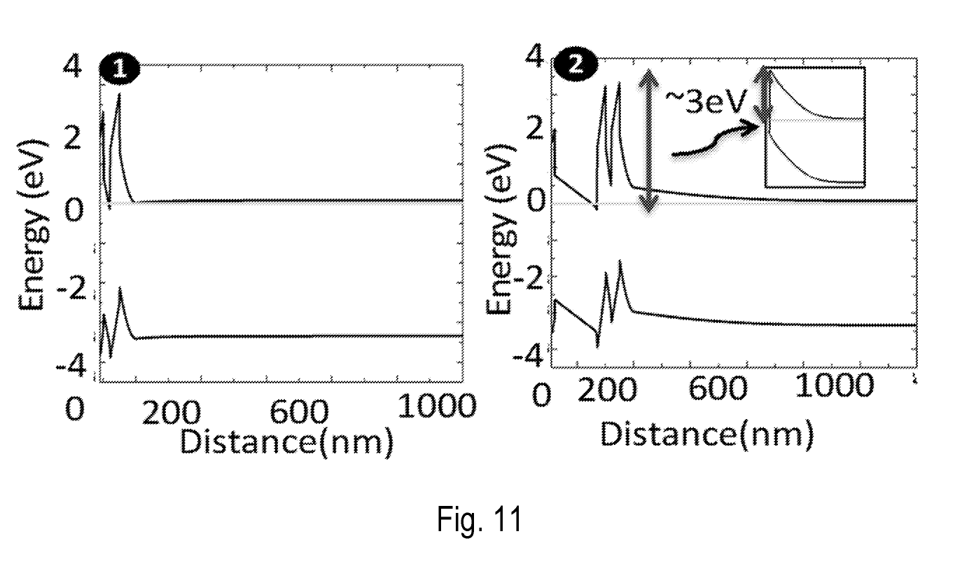

FIG. 11 shows the energy band diagrams for cross-section 1 (left) and cross-section 2 (right) of FIG. 10.

A person having ordinary skill in the art should appreciate that the functionality of this device was achieved by polarization engineering and not by way of doping or implantation. As a result, the fabrication of this device can be achieved in a single growth process, which maintains the as-grown material quality throughout the fabrication process. The breakdown field in these devices is expected to be close to the theoretical predicted values since the material quality was not compromised and the CBL was formed of a high quality, wider bandgap AlGaN material.

### Example 3

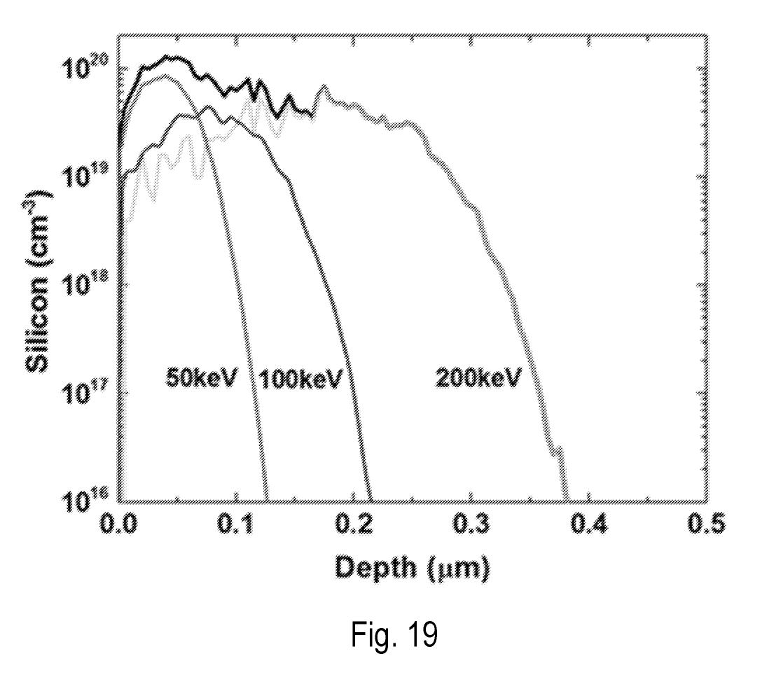

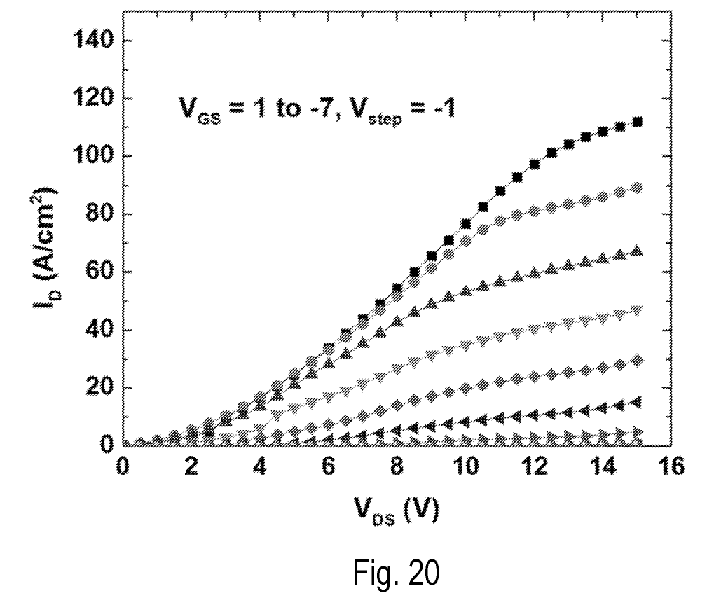

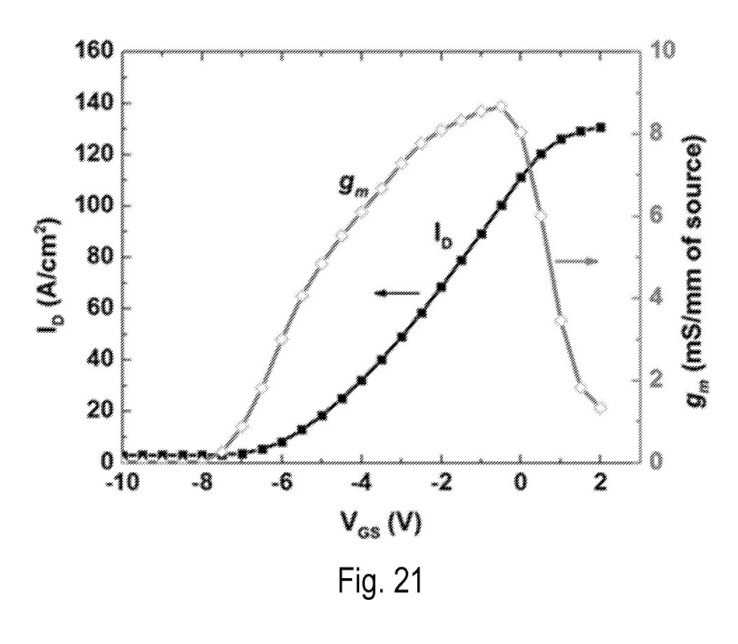

A computer simulation was performed to simulate the performance of an AlGaN/GaN CAVET, as illustrated in FIG. 15g and made using the method shown in FIG. 14. FIG. 19 represents the silicon profile as a function of depth under different implantation energies of 50 keV, 100 keV, and 200 keV. A 200 nm box donor profile was obtained. FIG. 20 represents the I_{D}-V_{DS} characteristics of the CAVET. The data indicates that the buried p-type CBL is reactivated successfully, and the aperture region was compensated by Si ion implantation successfully, thus confirming the efficacy of the method of making the CAVET. FIG. 21 represents the transfer characteristics and gₘ-V_{GS} of the CAVET. The threshold voltage was −5.2 V and the maximum output current was 130 A/cm².

### Example 4

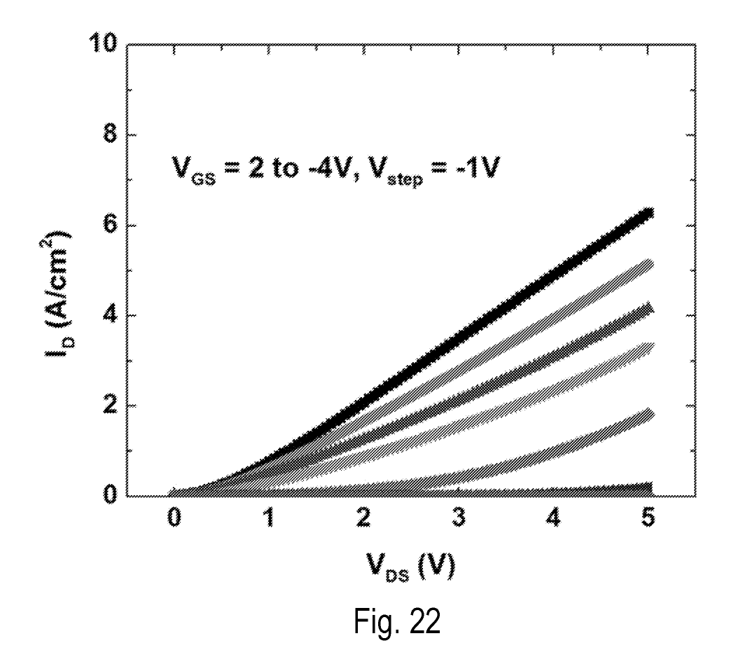

A computer simulation was performed to simulate the performance of a regrowth-free AlGaN/GaN CAVET, as illustrated in FIG. 17i and made using the method shown in FIG. 16. FIG. 22 represents the output I_{D}-V_{DS} of the regrowth-free CAVET. The results show that gate modulation works and that transistor characteristics are demonstrated.

1. A method for fabricating a semiconductor device, the method comprising:
obtaining, growing, or forming a GaN substrate, which includes a p-type current-blocking layer;
implanting Si, O, or H into the p-type current-blocking layer to form a current-aperture region for the semiconductor device; and
high-temperature annealing the substrate with the layers grown on top and implanted, thereby removing implantation-induced damage and electrically reactivating the current-aperture region.

2. The method of claim 1, wherein the current-blocking layer is exposed during the implanting.

3. The method of claim 1, wherein the current-blocking layer is buried by other III-Nitride layers during the implanting.

4. The method of claim 1, wherein the current-blocking layer is buried by a sacrificial mask layer during the implanting.

5. The method of claim 1, wherein the method further comprises forming (Al, Ga, In) N layers above the current-aperture region through regrowth in a growth chamber.

6. The method of claim 5, wherein the (Al, Ga, In) N layers are formed during an initial growth, which occurs before the implantation of the current-aperture region.

7. The method of claim 5, wherein the (Al, Ga, In) N layers are formed by regrowth through Molecular Beam Epitaxy (MBE) or Metal organic chemical vapor deposition (MOCVD).

8. The method of claim 5, wherein (Al, In, Ga) N structures in the semiconductor device are grown Nitrogen-polar.

9. The method of claim 5, wherein (Al, In, Ga) N structures in the semiconductor device are grown Ga-polar.

10. The method of claim 1, wherein growth of the semiconductor device structure is achieved by Molecular Beam Epitaxy (MBE) under a plasma or nitrogen-rich environment.

11. The method of claim 1, wherein growth of the semiconductor device structure is achieved by metal organic chemical vapor deposition.

12. The method of claim 1, wherein the method further comprises forming one or more source contacts on the GaN substrate.

13. The method of claim 12, wherein the one or more source contacts are formed through an annealing process.

14. The method of claim 12, wherein the one or more source contacts are formed through an implantation process.

15. The method of claim 1, wherein the semiconductor device comprises a lateral channel vertical junction field-effect transistor.

16. The method of claim 1, wherein the semiconductor device comprises a vertical electron transistor having at least one gate formed on an etched sidewall.

17. The method of claim 1, wherein the semiconductor device includes a dielectric layer comprised of an oxide-based dielectric.

18. The method of claim 1, wherein the semiconductor device includes a dielectric layer comprised of a non-oxide-based dielectric.

19. The method of claim 1, wherein the method further comprises:
creating one or more vias to expose at least a portion of the p-doped current-blocking layer positioned outside the current-aperture region; and
annealing the semiconductor device structure in the absence of hydrogen gas at a temperature above 600° C., thereby reactivating the at least a portion of the p-type current-blocking layer positioned outside the current-aperture region.

20. The method of claim 1, wherein the semiconductor device comprises a diode.

21. The method of claim 1, wherein the semiconductor device comprises a transistor.

22. The method of claim 21, wherein a field-plated structure comprises part of a gate of the transistor for electric field management.

23. The method of claim 21, wherein a field-plated structure comprises part of a source of the transistor for electric field management.

24. The method of claim 1, wherein a field-termination region resides in the vicinity of a high electric field region in the semiconductor device during off-state semiconductor device operation.

25. The method of claim 25, wherein the field-termination region is formed by implantation or diffusion of dopants, or regrowth of p-type wells.

26. The method of claim 25, wherein the field-termination region may or may not be active.

27. The method of claim 1, wherein a drain contact for the semiconductor device is located on a back of the wafer or substrate.

28. The method of claim 1, wherein a drain contact for the semiconductor device is located on a side surface formed by etching away top layers of the semiconductor device to form a via.

29. A semiconductor device fabricated by performing the following operations:
obtaining, growing, or forming a GaN substrate, which includes a p-type current-blocking layer;
implanting Si, O, or H into the p-type current-blocking layer to form a current-aperture region for the semiconductor device; and
high-temperature annealing the substrate with the layers grown on top and implanted, thereby removing implantation-induced damage and electrically reactivating the current-aperture region.

30. The semiconductor device of claim 19, wherein the operations further include forming (Al, Ga, In) N layers above the current-aperture region through regrowth in a growth chamber.

31. The semiconductor device of claim 29, wherein the semiconductor device comprises a lateral channel vertical junction field-effect transistor.

32. The semiconductor device of claim 29, wherein the semiconductor device comprises a vertical electron transistor having at least one gate formed on an etched sidewall.

33. The semiconductor device of claim 29, wherein the semiconductor device comprises a diode.
